(19) United States
(12) Patent Application Publication
(10) Pub. No.: US 2024/0162336 A1
(43) Pub. Date: May 16, 2024

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ming-Heng TSAI, Taipei City (TW); Chun-Sheng LIANG, Changhua County (TW)

(73) Assignee: Taiwan Semiconductor Manufacturing Company, Ltd., Hsinchu (TW)

(21) Appl. No.: 18/180,698

(22) Filed: Mar. 8, 2023

Related U.S. Application Data
(60) Provisional application No. 63/424,183, filed on Nov. 10, 2022.

(51) Int. Cl. H01L 29/775; H01L 29/06; H01L 29/423; H01L 29/66

(52) U.S. Cl. CPC H01L 29/775; H01L 29/0673; H01L 29/42392; H01L 29/66439

(57) ABSTRACT

Semiconductor structures and methods for manufacturing the same are provided. The semiconductor structure includes a first stack structure extends above the isolation structure, and the first stack structure includes a plurality of first nanostructures along a first direction. The semiconductor structure also includes a second stack structure formed adjacent to the first stack structure, and the second stack structure includes a plurality of second nanostructures along the first direction. A first dielectric wall between the first stack structure and the second stack structure, and the first dielectric wall is directly over a first portion of the isolation structure and surrounded by a second portion of the isolation structure, and a top surface of the first portion of the isolation structure is lower than a top surface of the second portion of the isolation structure.

### CROSS REFERENCE TO RELATED APPLICATIONS

This application claims the benefit of U.S. Provisional Application No. 63/424,183, filed on Nov. 10, 2022, and the entirety of which is incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., the minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIG. 1 illustrates a perspective view of a semiconductor structure, in accordance with some embodiments.

FIGS. 2A-1 to 2H-1 show cross-sectional representations of various stages of manufacturing the semiconductor structure shown along line I-I′ in FIG. 1, in accordance with some embodiments.

FIGS. 2A-2 to 2H-2 show top views of various stages of manufacturing the semiconductor structure, in accordance with some embodiments.

FIG. 2H′-1 illustrates a cross-sectional view of a semiconductor structure, in accordance with some embodiments.

FIG. 2H′-2 shows a top view of semiconductor structure of FIG. 2H′-1, in accordance with some embodiments.

FIG. 3 illustrates a perspective view of the semiconductor structure after the step of FIG. 2H-1, in accordance with some embodiments.

FIGS. 4A to 4E illustrate cross-sectional views of intermediate stages of manufacturing the semiconductor structure after FIG. 3, in accordance with some embodiments.

FIG. 4E′ illustrates a cross-sectional view of the semiconductor structure, in accordance with some embodiments.

FIG. 5 illustrates a cross-sectional view of a semiconductor structure, in accordance with some embodiments.

FIG. 5′ illustrates a cross-sectional view of a semiconductor structure, in accordance with some embodiments.

FIG. 6 illustrates a cross-sectional view of a semiconductor structure, in accordance with some embodiments.

FIG. 6′ illustrates a cross-sectional view of a semiconductor structure, in accordance with some embodiments.

FIGS. 7A to 7F illustrate cross-sectional views of intermediate stages of manufacturing the semiconductor structure after FIG. 4E, in accordance with some embodiments.

FIG. 7F′ illustrates a cross-sectional view of the semiconductor structure, in accordance with some embodiments.

FIG. 8 shows a top view of a semiconductor structure after FIG. 7F, in accordance with some embodiments.

FIG. 9A shows a top view of a semiconductor structure, in accordance with some embodiments.

FIG. 9B shows a top view of a semiconductor structure, in accordance with some embodiments.

FIG. 10A shows a top view of a semiconductor structure, in accordance with some embodiments.

FIG. 10B shows a top view of a semiconductor structure, in accordance with some embodiments.

FIG. 11A shows a top view of a semiconductor structure, in accordance with some embodiments.

FIG. 11B shows a top view of a semiconductor structure, in accordance with some embodiments.

FIG. 12A shows a top view of a semiconductor structure, in accordance with some embodiments.

FIG. 12B shows a top view of a semiconductor structure, in accordance with some embodiments.

FIG. 13A shows a top view of a semiconductor structure, in accordance with some embodiments.

FIG. 13B shows a top view of a semiconductor structure, in accordance with some embodiments.

FIG. 14A shows a top view of a semiconductor structure, in accordance with some embodiments.

FIG. 14B shows a top view of a semiconductor structure, in accordance with some embodiments.

FIG. 15A shows a top view of a semiconductor structure, in accordance with some embodiments.

FIG. 15B shows a top view of a semiconductor structure, in accordance with some embodiments.

FIGS. 16A to 16L illustrate top views of the semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a first stack structure and a second stack structure formed over a substrate. The first portion of the isolation structure is formed over the substrate and between the first stack structure and the second stack structure. A dielectric wall is formed over the first portion of the isolation structure. The second portion of the isolation structure is formed after the dielectric wall is formed. Since the dielectric wall is formed after the first portion of the isolation structure is formed, and the dielectric wall is removed by CMP process, rather than by the etching process. The risk of over-etching issue of the side of the dielectric wall and the shrinkage issue of the dielectric wall are reduced. In addition, the dielectric wall is isolated from the substrate by the isolation structure, and therefore the leakage is reduced. Therefore, the performance of the semiconductor structure is improved.

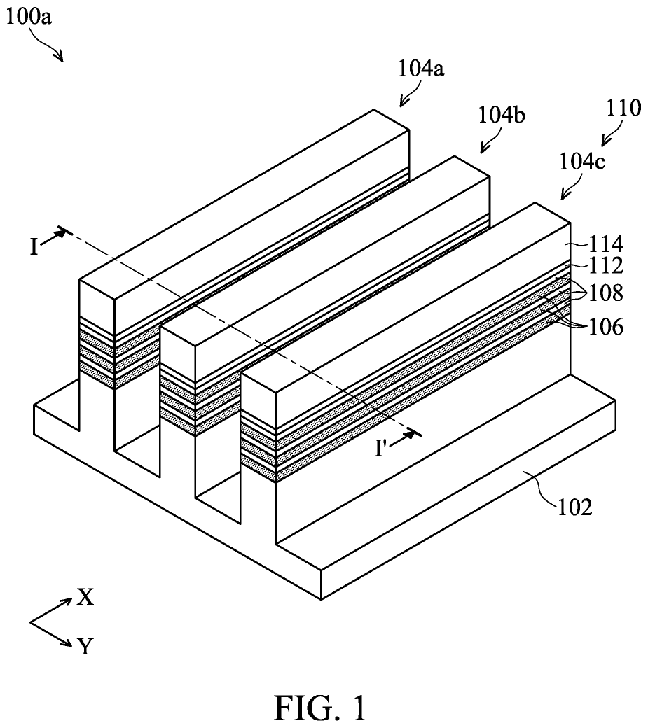

FIG. 1 illustrates a perspective view of a semiconductor structure 100a, in accordance with some embodiments. As shown in FIG. 1, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

After the first semiconductor material layers 106 and the second semiconductor material layers 108 are formed as a semiconductor material stack over the substrate 102, the semiconductor material stack is patterned to form a first stack structure 104a, a second stack structure 104b, and a third stack structure 140c, in accordance with some embodiments. In some embodiments, each of the first stack structure 104a, the second stack structure 104b, and the third stack structure 140c includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

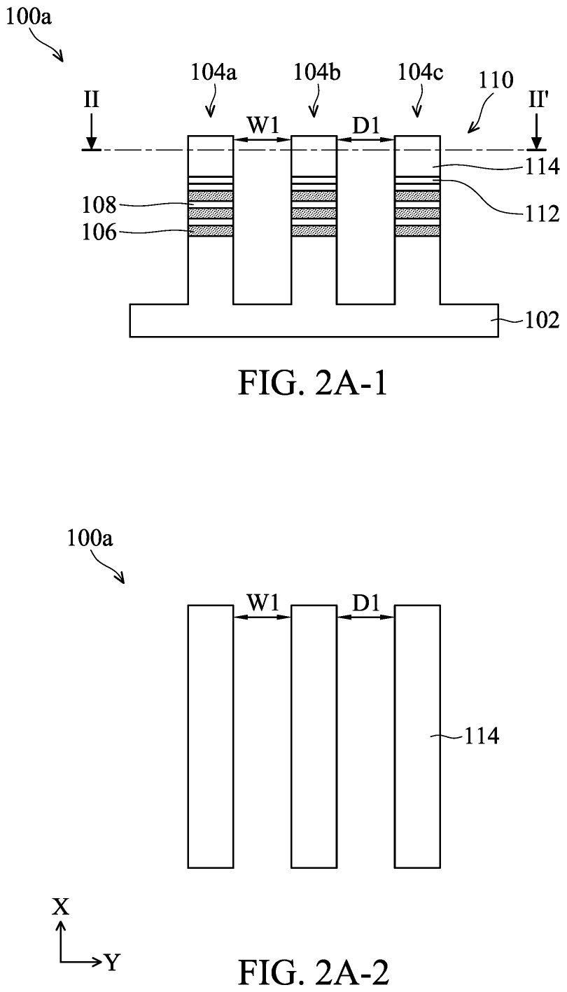

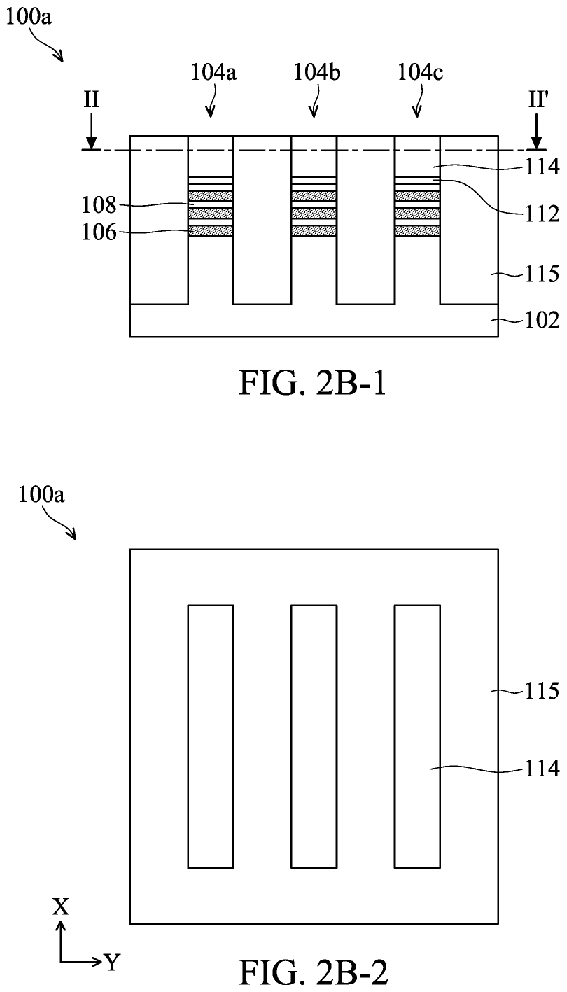

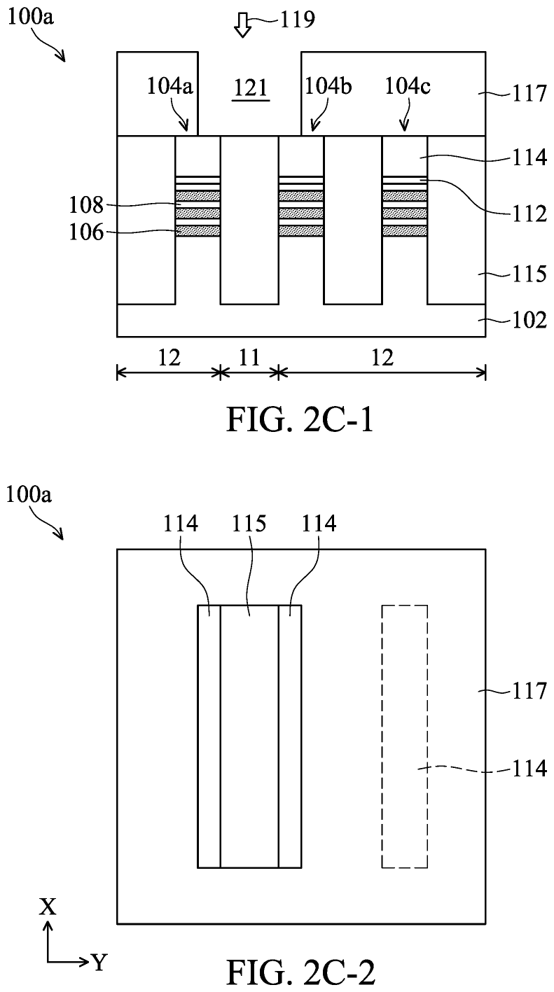

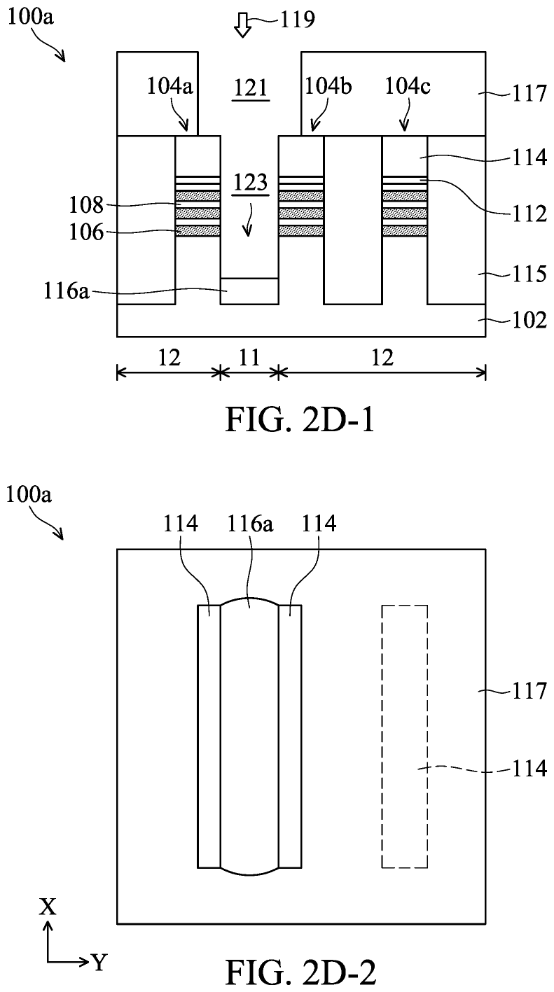

FIGS. 2A-1 to 2H-1 show cross-sectional representations of various stages of manufacturing the semiconductor structure 100a shown along line I-I′ in FIG. 1, in accordance with some embodiments. FIGS. 2A-2 to 2H-2 show top views of various stages of manufacturing the semiconductor structure 100a, in accordance with some embodiments.

FIG. 2A-2 shows a top view of semiconductor structure 100a shown along line II-II′ in FIG. 2A-1, in accordance with some embodiments.

As shown in FIGS. 2A-1 and 2A-2, the mask structure 110 is formed over the first stack structure 104a, the second stack structure 104b, and the third stack structure 140c, in accordance with some embodiments. The first stack structure 104a, the second stack structure 104b, and the third stack structure 140c are formed along the first direction (e.g. the X-axis).

In some embodiments, there is a first width W₁ between the first stack structure 104a and the second stack structure 104b along the second direction (e.g. the Y-axis). In some embodiments, there is a first distance D₁ between the second stack structure 104b and the third stack structure 140c along the second direction (e.g. the Y-axis). In some embodiments, the first width W₁ is substantially to the first distance D₁.

FIG. 2B-2 shows a top view of semiconductor structure 100a shown along line II-II′ in FIG. 2B-1, in accordance with some embodiments.

Next, as shown in FIGS. 2B-1 and 2B-2, an isolation material 115 is formed over the first stack structure 104a, the second stack structure 104b, the third stack structure 140c and the mask structure 110, in accordance with some embodiments. Afterwards, the top portion of the isolation material 115 is removed by a planarization process such as CMP process. As a result, the top surface of the mask structure 110 is exposed.

In some embodiments, the isolation material 115 is made of silicon oxide, silicon nitride, silicon oxynitride (SiON), another suitable insulating material, or a combination thereof. In some embodiments, the isolation material 115 is formed by chemical vapor deposition (CVD), atomic vapor deposition (ALD), physical vapor deposition (PVD), another suitable method, or a combination thereof.

FIG. 2C-2 shows a top view of semiconductor structure 100a when seen from an arrow direction 119, in accordance with some embodiments.

Next, as shown in FIGS. 2C-1 and 2C-2, a hard mask layer 117 is formed over the mask structure 110, and then the hard mask layer 117 is patterned by a patterning process to form an opening 121, in accordance with some embodiments. A portion of the isolation material 115 in the first region 11 is exposed by the opening 121 of the hard mask layer 117.

The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process includes a dry etching process or a wet etching process.

FIG. 2D-2 shows a top view of semiconductor structure 100a when seen from the arrow direction 119, in accordance with some embodiments.

Afterwards, as shown in FIGS. 2D-1 and 2D-2, the top portion of the exposed portion of the isolation material 115 is removed to form a recess 123, in accordance with some embodiments. As a result, the first portion 116a of the isolation structure 116 in the first region 11 is obtained.

The first portion 116a of the isolation structure 116 in the first region 11 is lower than the top surface of the mask structure 110. In addition, the first portion 116a of the isolation structure 116 in the first region 11 is lower than the top surfaces of the first stack structure 104a, the second stack structure 104b, and the third stack structure 140c. In some embodiments, the top surface of the first portion 116a of the isolation structure 116 in the first region 11 is lower than the bottom surface of the bottommost first semiconductor layer 106 of the first stack structure 104a.

In some embodiments, the top portion of the exposed portion of the isolation material 115 is removed by an etching process, such as wet etching process or a dry etching process.

As shown in FIG. 2D-2, the sidewall of the first portion 116a of the isolation structure 116 in the first region 11 extends beyond the sidewall of the nitride layer 114 of the mask structure 110. In some embodiments, the first portion 116a of the isolation structure 116 in the first region 11 has a C shape structure when seen from a top view.

FIG. 2E-2 shows a top view of semiconductor structure 100a shown along line II-II′ in FIG. 2E-1, in accordance with some embodiments.

Next, as shown in FIGS. 2E-1 and 2E-2, a dielectric wall 124 is formed in the recess 123, over the first portion 116a of the isolation structure 116 and over the nitride layer 114 of the mask structure 110, in accordance with some embodiments.

In some embodiments, the dielectric wall 124 is made of SiN, SiCN, SiOC, SiOCN or applicable material. In some embodiments, the dielectric wall 124 is formed by chemical vapor deposition (CVD), atomic vapor deposition (ALD), physical vapor deposition (PVD), another suitable method, or a combination thereof.

FIG. 2F-2 shows a top view of semiconductor structure 100a shown along line II-II′ in FIG. 2F-1, in accordance with some embodiments.

Afterwards, as shown in FIGS. 2F-1 and 2F-2, the top portion of the dielectric wall 124 is removed by a planarization process such as CMP process. As a result, the top surface of the nitride layer 114 of the mask structure 110 is exposed. The dielectric wall 124 and the isolation material 115 are made of different materials, and therefore an interface is between the dielectric wall 124 and the isolation material 115. The interface is lower than the bottom surface of the bottommost first semiconductor layer 106 of the first stack structure 104a.

The dielectric wall 124 is between and in direct contact with the first stack structure 104a and the second stack structure 104b. The top surface of the dielectric wall 124 is substantially level with the top surface of the nitride layer 114 of the mask structure 110.

As shown in FIG. 2F-2, the sidewall of the dielectric wall 124 extends beyond the sidewall of the nitride layer 114 of the mask structure 110 when seen from a top view. In other words, the sidewall of the dielectric wall 124 extends beyond the sidewall of the first stack structure 104a. In some embodiments, there is a void 125 in the dielectric wall 124 when seen from a top view.

FIG. 2G-2 shows a top view of semiconductor structure 100a shown along line II-II′ in FIG. 2G-1, in accordance with some embodiments.

Afterwards, as shown in FIGS. 2G-1 and 2G-2, the mask structure 110 over the first stack structure 104a, the second stack structure 104b and the third stack structure 104c is removed, in accordance with some embodiments. As a result, the top surface of the second semiconductor layer 108 of the first stack structure 104a is exposed. The top surface of the second semiconductor layer 108 of the second stack structure 104b is also exposed. In addition, the top surface of the isolation material 115 is higher than the top surface of the second semiconductor layer 108 of the first stack structure 104a. In some embodiments, the mask structure 110 is removed by an etching process, such as wet etching process or a dry etching process.

FIG. 2H-2 shows a top view of semiconductor structure 100a when seen from the arrow direction 119, in accordance with some embodiments.

Next, as shown in FIGS. 2H-1 and 2H-2, the top portion of the isolation material 115 in the second region 12 is removed to form the second portion 116b of the isolation structure 116, in accordance with some embodiments.

The dielectric wall 124 extends above the top surface of the first stack structure 104a and the top surface of the second stack structure 104b. In other words, the dielectric wall 124 has a protruding portion which is higher than the top surface of the first stack structure 104a and the top surface of the second stack structure 104b. The protruding portion of the dielectric wall 124 has a first height H₁. In some embodiments, the first height H₁ of the protruding portion of the dielectric wall 124 is in a range from about 3 nm to about 30 nm.

It should be noted that the isolation structure 116 has the first portion 116a in the first region 11 and the second portion 116b in the second region 12. The dielectric wall 124 is directly over the first portion 116a of the isolation structure 116 and surrounded by the second portion 116b of the isolation structure 116. The first portion 116a of the isolation structure 116 is formed before the dielectric wall 124 is formed, and the second portion 116b of the isolation structure 116 is formed after the dielectric wall 124 is formed. The top surface of the first portion 116a of the isolation structure 116 in the first region 11 is lower than the top surface of the second portion 116b of the isolation structure 116 in the second region 12. In addition, the bottom surface of the first portion 116a of the isolation structure 116 is substantially level with the bottom surface of the second portion 116b of the isolation structure 116.

It is appreciated that although the cross-sectional views shown in FIGS. 2A-1 to 2H-1 and 2A-2 to 2H-2 are described with reference to a method, the structures are not limited to the method but rather may stand alone separate of the method.

FIG. 2H′-1 illustrates a cross-sectional view of a semiconductor structure 100b, in accordance with some embodiments. FIG. 2H′-2 shows a top view of semiconductor structure 100b of FIG. 2H′-1, in accordance with some embodiments. The semiconductor structure 100b of FIG. 2H′-1 and FIG. 2H′-2 include elements that are similar to, or the same as, elements of the semiconductor structure 100a of FIG. 2H-1, the difference between the FIG. 2H′-1 and FIG. 2H-1 is a liner dielectric layer 122 is formed before the dielectric wall 124 is formed. The dielectric wall 124 is surrounded by the liner dielectric layer 122. The liner dielectric layer 122 is an adhesion layer to improve the adhesion between the dielectric wall 124 and the first stack structure 104a and the second stack structure 104b. The liner dielectric layer 122 is in direct contact with the first stack structure 104a and the second stack structure 104b.

The liner dielectric layer 122 is made of oxide, such as silicon oxide. In some embodiments, the liner dielectric layer 122 is formed by chemical vapor deposition (CVD), atomic vapor deposition (ALD), physical vapor deposition (PVD), another suitable method, or a combination thereof.

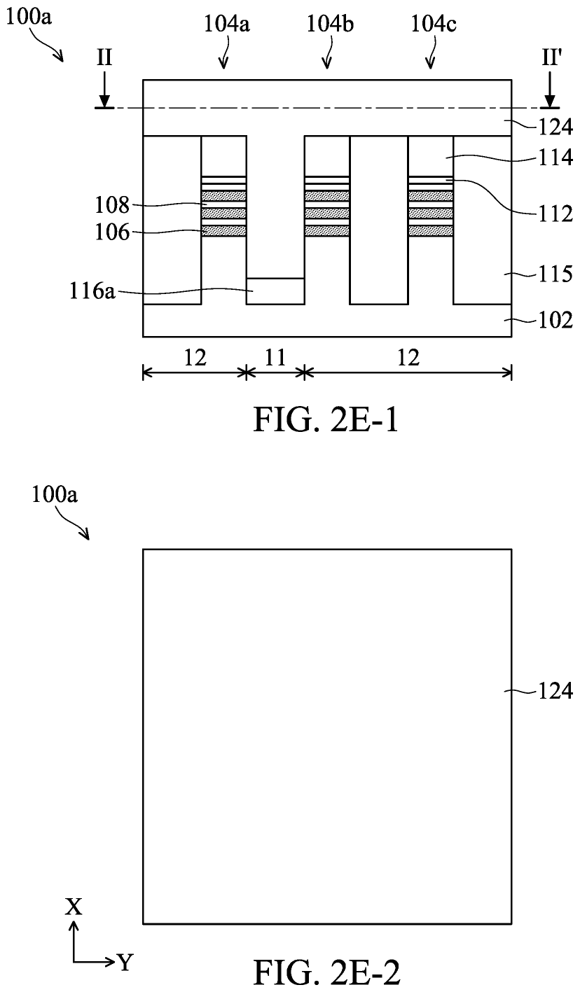

FIG. 3 illustrates a perspective view of the semiconductor structure 100a after the step of FIG. 2H-1, in accordance with some embodiments.

As shown in FIG. 3, a dummy gate structure 128 is formed across the first stack structure 104a, the second stack structure 104b, the third stack structure 104c and over the second portion 116b of the isolation structure 116, in accordance with some embodiments. The dummy gate structure 128 may be used to define the source/drain regions and the channel regions of the resulting semiconductor structure 100a.

In some embodiments, the dummy gate structure 128 includes a dummy gate dielectric layer 130 and dummy gate electrode layers 132. In some embodiments, the dummy gate dielectric layer 130 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 130 is formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layer 132 is formed using chemical vapor deposition (CVD), physical vapor deposition (PVD), or a combination thereof.

In some embodiments, a hard mask layer 134 is formed over the dummy gate structure 128. In some embodiments, the hard mask layer 134 includes multiple layers, such as an oxide layer and a nitride layer. In some embodiments, the oxide layer is silicon oxide, and the nitride layer is silicon nitride.

The formation of the dummy gate structure 128 may include conformally forming a dielectric material as the dummy gate dielectric layer 130. Afterwards, a conductive material may be formed over the dielectric material as the dummy gate electrode layer 132, and the hard mask layer 134 may be formed over the conductive material. Next, the dielectric material and the conductive material may be patterned through the hard mask layer 134 to form the dummy gate structure 128.

After the dummy gate structure 128 is formed, gate spacers 136 are formed along and covering opposite sidewalls of the dummy gate structure 128 and fin spacers 138 are formed along and covering opposite sidewalls of the source/drain regions of the first stack structure 104a and the second stack structure 104b, in accordance with some embodiments.

The gate spacers 136 may be configured to separate source/drain structures from the dummy gate structure 128 and support the dummy gate structure 128, and the fin spacers 138 may be configured to constrain a lateral growth of subsequently formed source/drain structure and support the first stack structure 104a and the second stack structure 104b.

In some embodiments, the gate spacers 136 and the fin spacers 138 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacers 136 and the fin spacers 138 may include conformally depositing a dielectric material covering the dummy gate structure 128, the first stack structure 104a, the second stack structure 104b, and the isolation structure 116 over the substrate 102, and performing an anisotropic etching process, such as dry plasma etching, to remove the dielectric layer covering the top surfaces of the dummy gate structure 128, the first stack structure 104a, the second stack structure 104b, and portions of the isolation structure 116.

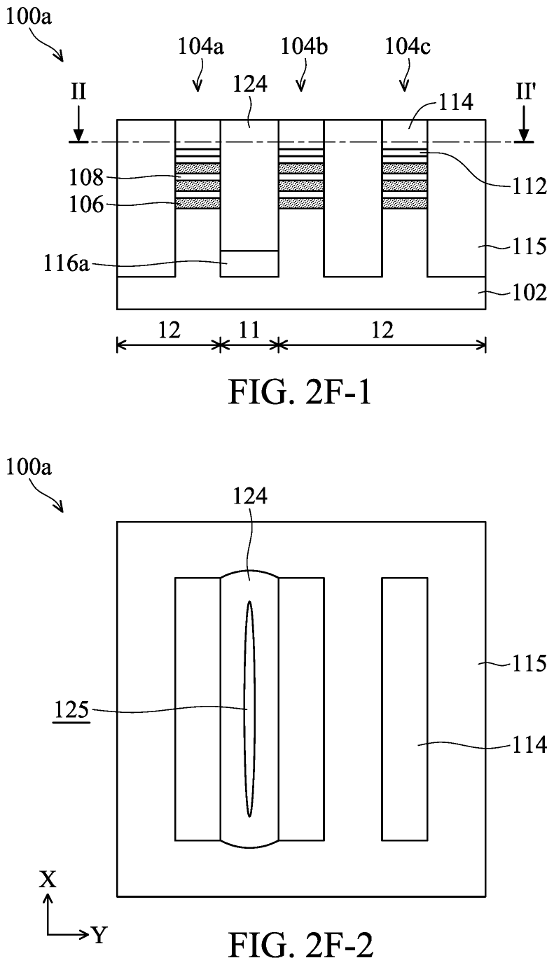

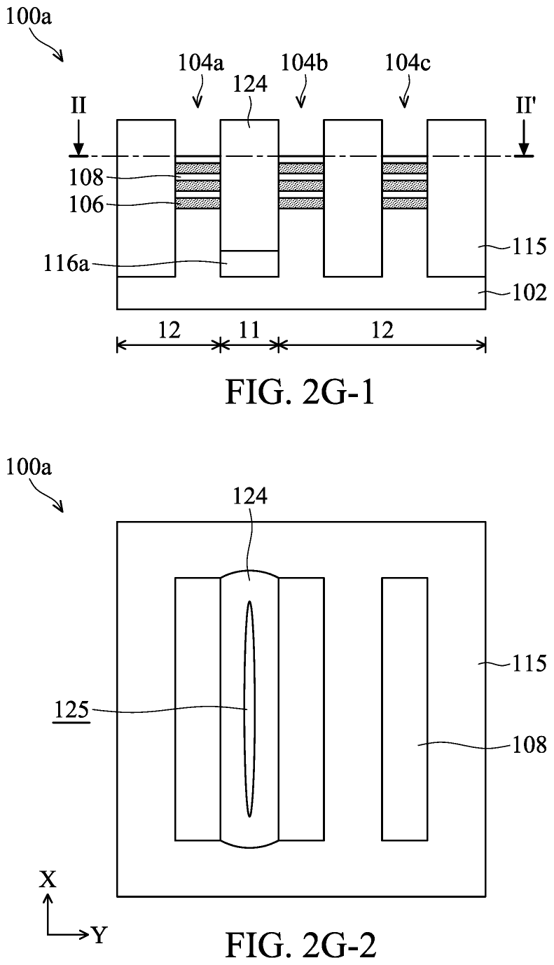

FIGS. 4A to 4E illustrate cross-sectional views of intermediate stages of manufacturing the semiconductor structure 100a after FIG. 3, in accordance with some embodiments. FIG. 4A illustrates a cross-sectional representation of the semiconductor structure 100a shown along line A-A′ in FIG. 3, in accordance with some embodiments.

As shown in FIG. 4A, the dielectric wall 124 is between the first stack structure 104a and the second stack structure 104b. The isolation structure 116 includes the first portion 116a in the first region 11 and the second portion 116b in the second region 12. The dielectric wall 124 is directly above the first portion 116a of the isolation structure 116 in the first region 11. The top surface of the first portion 116a of the isolation structure 116 is lower than the top surface of the second portion 116b of the isolation structure 116.

Afterwards, as shown in FIG. 4B, after the gate spacers 136 and the fin spacers 138 are formed, the source/drain (S/D) regions of the first stack structure 104a, the second stack structure 104b, and the third stack structure 104c are recessed to form source/drain (S/D) recesses 140, as shown in in accordance with some embodiments. More specifically, the first semiconductor material layers 106 and the second semiconductor material layers 108 not covered by the dummy gate structures 128 and the gate spacers 136 are removed in accordance with some embodiments. In addition, some portions of the base fin structure 105 are also recessed to form curved top surfaces. The source/drain region(s) may refer to a source or a drain, individually or collectively dependent upon the context.

In some embodiments, the first stack structure 104a, the second stack structure 104b and the third stack structure 104c are recessed by performing an etching process. The etching process may be an anisotropic etching process, such as dry plasma etching, and the dummy gate structure 128 and the gate spacers 136 are used as etching masks during the etching process. In some embodiments, the fin spacers 138 are also recessed to form lowered fin spacers 138.

Afterwards, after the source/drain recesses 140 are formed, the first semiconductor material layers 106 exposed by the source/drain recesses 140 are laterally recessed to form notches (not shown), in accordance with some embodiments.

In some embodiments, an etching process is performed on the semiconductor structure 100a to laterally recess the first semiconductor material layers 106 of the first stack structure 104a, the second stack structure 104b and the third stack structure 104c from the source/drain recesses 140. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

Next, inner spacers (not shown) are formed in the notches (not shown) between the second semiconductor material layers 108, in accordance with some embodiments. The inner spacers are configured to separate the source/drain structures and the gate structures formed in subsequent manufacturing processes in accordance with some embodiments. In some embodiments, the inner spacers are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layers are formed by a deposition process, such as chemical vapor deposition (CVD) process, atomic layer deposition (ALD) process, another applicable process, or a combination thereof

Next, as shown in FIG. 4C, a first S/D structure 146a is formed in one of the S/D recess 140, in accordance with some embodiments. The first S/D structure 146a extends above the top surface of fin spacer 138. In addition, a portion of the first S/D structure 146a is in direct contact with the dielectric wall 124. More specifically, the portion of the first S/D structure 146a is in direct contact with the sidewall of the dielectric wall 124. The top surface of the dielectric wall 124 is higher than the top surface of the first S/D structure 146a.

In some embodiments, the first S/D structures 146a is made of any applicable material, such as Ge, Si, GaAs, AlGaAs, SiGe, GaAsP, SiP, SiC, SiCP, or a combination thereof. In some embodiments, the first S/D structure 146a is formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof.

In some embodiments, the first S/D structure 146a is in-situ doped during the epitaxial growth process. For example, the first S/D structure 146a may be the epitaxially grown SiGe doped with boron (B). For example, the first S/D structure 146a may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the first S/D structures 146a are doped in one or more implantation processes after the epitaxial growth process.

Afterwards, as shown in FIG. 4D, a second S/D structure 146b is formed in the S/D recess 140, in accordance with some embodiments. In addition, the second S/D structure 146b is in direct contact with the dielectric wall 124. More specifically, the second S/D structure 146b is in direct contact with the sidewalls of the dielectric wall 124. The bottom surface of the dielectric wall 124 is lower than the bottom surface of the first S/D structure 146a and the bottom surface of the second S/D structure 146b. In other words, the top surface of the first portion 116a of the isolation structure 116 is lower than the bottom surface of the first S/D structure 146a and the bottom surface of the second S/D structure 146b. The top surface of the dielectric wall 124 is higher than the top surface of the first S/D structure 146a and the top surface of the second S/D structure 146b.

In some embodiments, the second S/D structures 146b is made of any applicable material, such as Ge, Si, GaAs, AlGaAs, SiGe, GaAsP, SiP, SiC, SiCP, or a combination thereof. In some embodiments, the second S/D structure 146b is formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof.

In some embodiments, the second S/D structure 146b is in-situ doped during the epitaxial growth process. For example, the second S/D structure 146b may be the epitaxially grown SiGe doped with boron (B). For example, the second S/D structure 132b may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the second S/D structures 146b are doped in one or more implantation processes after the epitaxial growth process.

Next, as shown in FIG. 4E, after the first S/D structure 146a and second S/D structures 146b are formed, a contact etch stop layer (CESL) 148 is conformally formed to cover the first S/D structure 146a and the second S/D structure 146b and an interlayer dielectric (ILD) layer 150 is formed over the contact etch stop layers 148, in accordance with some embodiments.

It should be noted that the space between the first S/D structure 146a and the second S/D structure 146b is filled with the CESL 148. The CESL 148 is in direct contact with the top surface of the dielectric wall 124.

In some embodiments, the CESL 148 is made of a dielectric materials, such as silicon nitride, silicon oxide, silicon oxynitride, another suitable dielectric material, or a combination thereof. The dielectric material for the CESL 148 may be conformally deposited over the semiconductor structure by performing chemical vapor deposition (CVD), ALD, other application methods, or a combination thereof.

The ILD layer 150 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 150 may be formed by chemical vapor deposition (CVD), physical vapor deposition, (PVD), atomic layer deposition (ALD), or other applicable processes.

After the CESL 148 and the ILD layer 150 are deposited, a planarization process such as CMP or an etch-back process may be performed until the gate electrode layers 130 of the dummy gate structures 128 are exposed.

FIG. 4E′ illustrates a cross-sectional view of the semiconductor structure 100b, in accordance with some embodiments. The semiconductor structure 100b of FIG. 4E′ includes elements that are similar to, or the same as, elements of the semiconductor structure 100a of FIG. 4E, the difference between the FIG. 4E′ and FIG. 4E is the liner dielectric layer 122 is formed before the dielectric wall 124 is formed. The dielectric wall 124 is surrounded by the liner dielectric layer 122. The liner dielectric layer 122 is an adhesion layer. The liner dielectric layer 122 is in direct contact with the first S/D structure 146a and the second S/D structure 146b.

The bottom surface of the liner dielectric layer 122 is lower than the bottom surface of the first S/D structure 146a and the bottom surface of the second S/D structure 146b. The top surface of the liner dielectric layer 122 is higher than the top surface of the first S/D structure 146a and the top surface of the second S/D structure 146b. The liner dielectric layer 122 is made of oxide, such as silicon oxide. In some embodiments, the liner dielectric layer 122 is formed by chemical vapor deposition (CVD), atomic vapor deposition (ALD), physical vapor deposition (PVD), another suitable method, or a combination thereof.

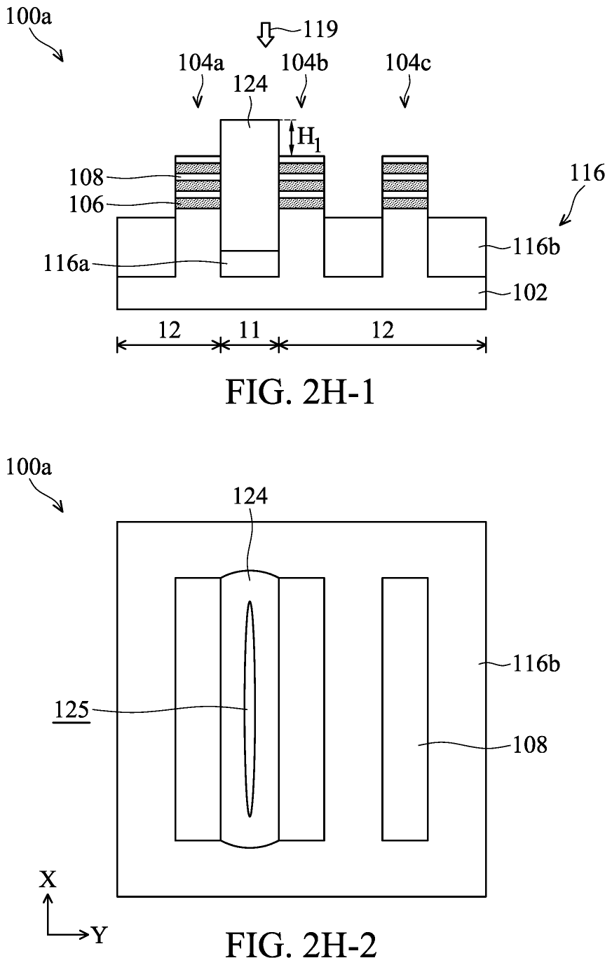

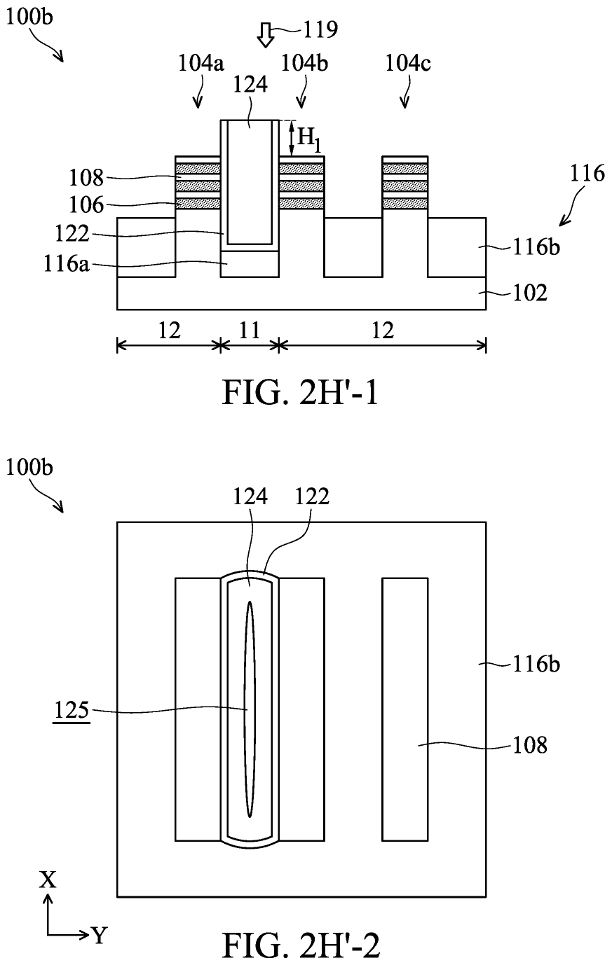

FIG. 5 illustrates a cross-sectional view of a semiconductor structure 100c, in accordance with some embodiments. The semiconductor structure 100c of FIG. 5 includes elements that are similar to, or the same as, elements of the semiconductor structure 100a of FIG. 4E, the difference between the FIG. 5 and FIG. 4E is the bottom surface of the dielectric wall 124 is higher than the bottom surface of the first S/D structure 146a and the bottom surface of the second S/D structure 146b.

FIG. 5′ illustrates a cross-sectional view of a semiconductor structure 100d, in accordance with some embodiments. The semiconductor structure 100d of FIG. 5′ includes elements that are similar to, or the same as, elements of the semiconductor structure 100c of FIG. 5, the difference between the FIG. 5′ and FIG. 5 is the liner dielectric layer 122 is formed before the dielectric wall 124 is formed. The dielectric wall 124 is surrounded by the liner dielectric layer 122. The liner dielectric layer 122 is in direct contact with the first S/D structure 146a and the second S/D structure 146b.

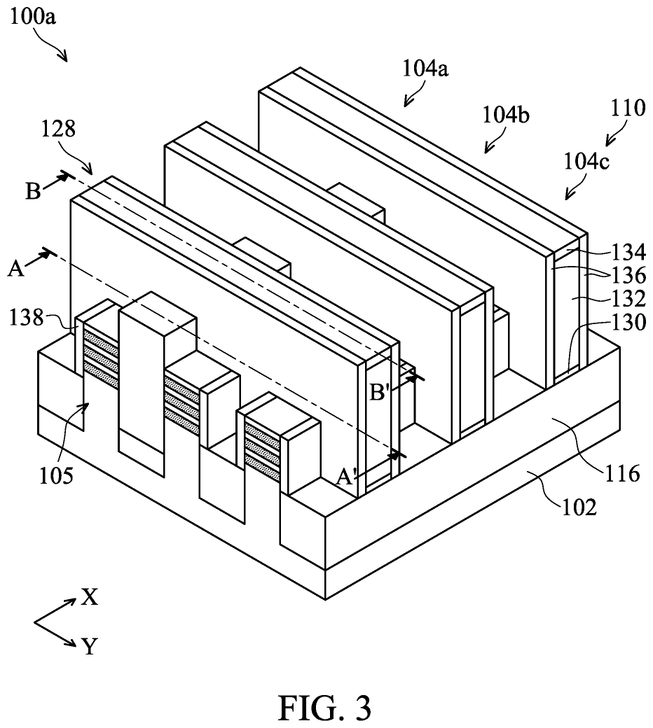

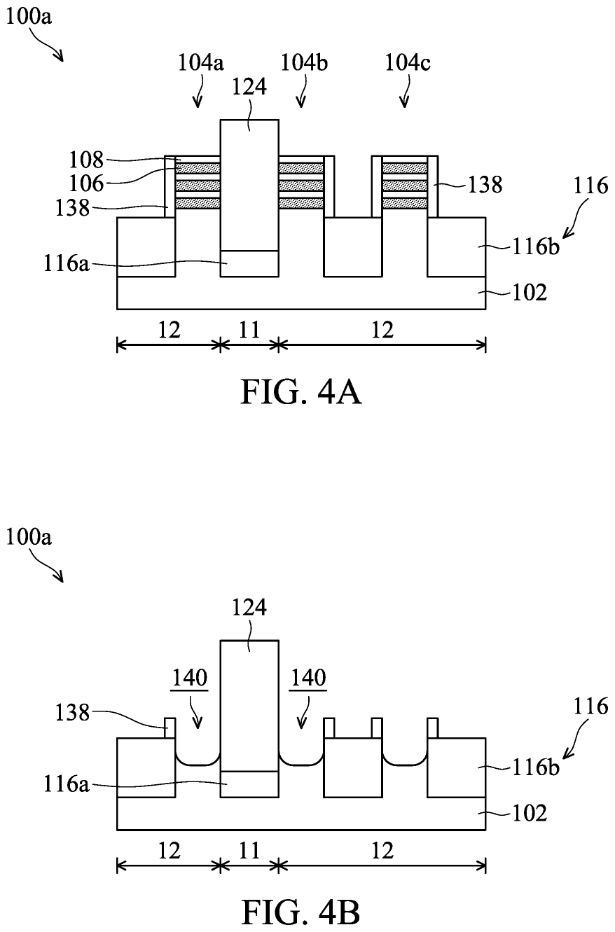

FIG. 6 illustrates a cross-sectional view of a semiconductor structure 100e, in accordance with some embodiments. The semiconductor structure 100e of FIG. 6 includes elements that are similar to, or the same as, elements of the semiconductor structure 100a of FIG. 4E, the difference between the FIG. 6 and FIG. 4E is the top surface of the dielectric wall 124 is lower than the top surface of the first S/D structure 146a and the top surface of the second S/D structure 146b.

FIG. 6′ illustrates a cross-sectional view of a semiconductor structure 100f, in accordance with some embodiments. The semiconductor structure 100f of FIG. 6′ includes elements that are similar to, or the same as, elements of the semiconductor structure 100e of FIG. 6, the difference between the FIG. 6′ and FIG. 6 is the liner dielectric layer 122 is formed before the dielectric wall 124 is formed. The dielectric wall 124 is surrounded by the liner dielectric layer 122. The liner dielectric layer 122 is in direct contact with the first S/D structure 146a and the second S/D structure 146b.

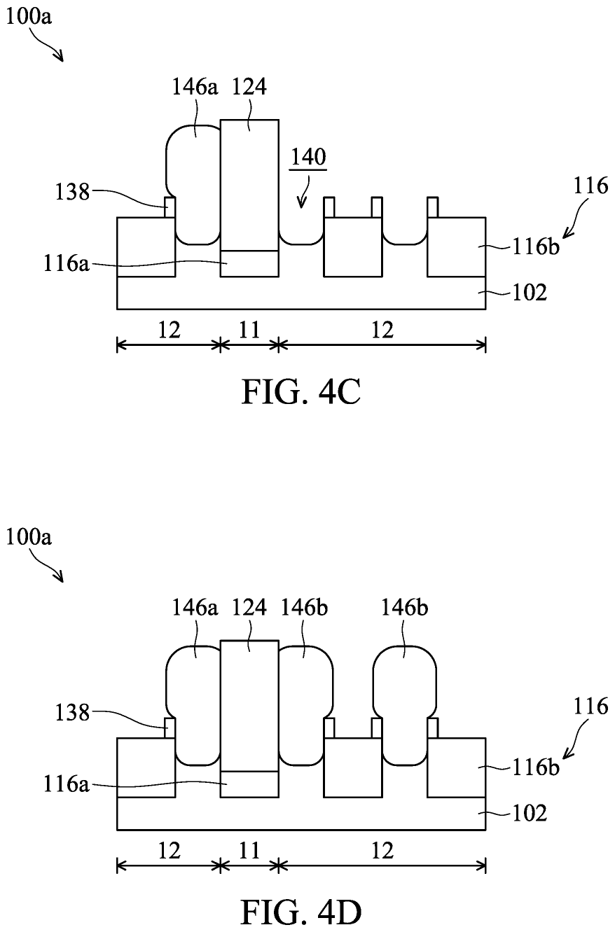

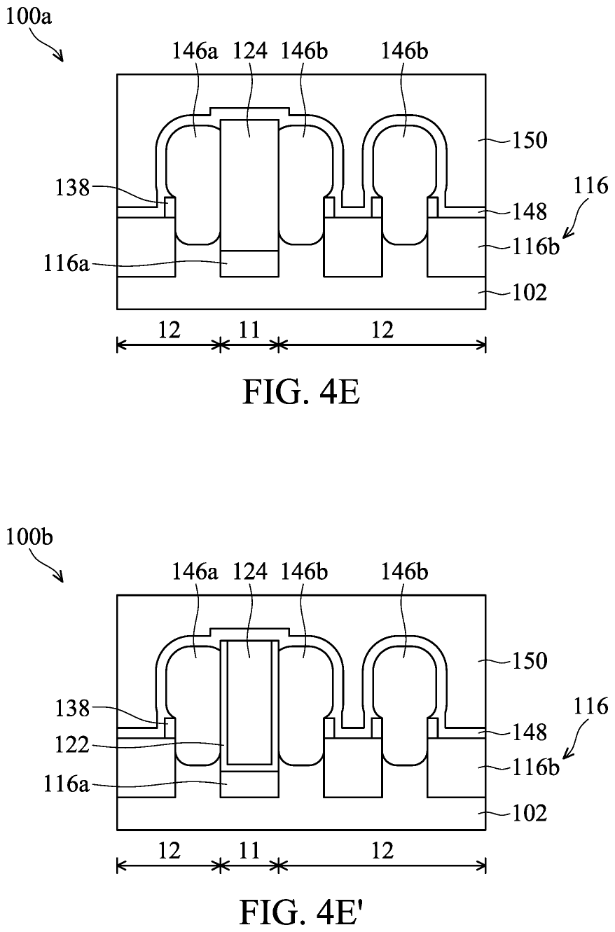

FIGS. 7A to 7F illustrate cross-sectional views of intermediate stages of manufacturing the semiconductor structure 100a after FIG. 4E, in accordance with some embodiments. FIG. 7A illustrates a cross-sectional representation of the semiconductor structure 100a shown along line B-B′ in FIG. 3, in accordance with some embodiments.

As shown in FIG. 7A, the dummy gate structure 128 is formed over the first stack structure 104a, the second stack structure 104b, the third stack structure 104c, the dielectric wall 124 and the isolation structure 126, in accordance with some embodiments. The hard mask layer 134 is formed over the dummy gate structure 128.

Next, as shown in FIG. 7B, the dummy gate structure 128 is removed to exposed the first stack structure 104a, the second stack structure 104b and the third stack structure 104c, in accordance with some embodiments. As a result, a portion of the dielectric wall 124 is exposed.

It should be noted that, the dielectric wall 124 along line B-B′ in FIG. 3, is directly below the dummy gate structure 128 and protected by the dummy gate structure 128, it is not removed when the process for forming the first S/D structure 132a and the second S/D structure 132b.

The removal process may include one or more etching processes. For example, when the dummy gate electrode layer 132 is polysilicon, a wet etchant such as a tetramethylammonium hydroxide (TMAH) solution may be used to selectively remove the dummy gate electrode layer 132. Afterwards, the dummy gate dielectric layer 130 may be removed using a plasma dry etching, a dry chemical etching, and/or a wet etching.

Afterwards, as shown in FIG. 7C, the first semiconductor material layers 106 are removed to form a trench 151, and the nanostructures 108′ with the second semiconductor material layers 108 is remaining, in accordance with some embodiments. The first S/D structure 146a and the second S/D structure 146b are attached to the nanostructures 108′. The topmost surface of the dielectric wall 124 is higher than the topmost surface of the topmost nanostructures 108′.

The first semiconductor material layers 106 may be removed by performing a selective wet etching process, such as APM (e.g., an ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

Next, as shown in FIG. 7D, after the nanostructures 108′ are formed, an interfacial layer 152 is formed to surround the nanostructures 108′ and over the isolation structure 110, and a gate dielectric layer 154 is formed on the interfacial layer 154, in accordance with some embodiments. The interfacial layer 152 is in direct contact with the dielectric wall 124.

In some embodiments, the interfacial layer 152 is oxide layer formed around the nanostructures 108′. In some embodiments, the interfacial layer 152 is formed by performing a thermal process. In some embodiments, the gate dielectric layers 154 are formed over the interfacial layers 152, so that the nanostructures 108′ are surrounded (e.g. wrapped) by the gate dielectric layers 154. In some embodiments, the gate dielectric layers 154 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate dielectric layers 154 are formed using chemical vapor deposition (CVD), atomic layer deposition (ALD), another applicable method, or a combination thereof.

Next, as shown in FIG. 7E, a first gate electrode layer 158a is formed to surround the nanostructures 108′, and then a second gate electrode layer 158b is formed to surround the nanostructures 108′, in accordance with some embodiments. A first gate structure 162a is constructed by the interfacial layer 152, the gate dielectric layer 154, and the first gate electrode layer 158a.

The first gate structure 162a is wrapped around the nanostructures 108′ of the first stack structure 104a. In some embodiments, the first gate electrode layer 158a is formed on the gate dielectric layer 146. In some embodiments, the first gate electrode layer 158a is made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the first gate electrode layer 158a is formed using chemical vapor deposition (CVD), atomic layer deposition (ALD), electroplating, another applicable method, or a combination thereof.

Other conductive layers, such as work function metal layers, may also be formed in the first gate structure 142a, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

The second gate electrode layer 148b is formed in the second region 12 to surround the nanostructures 108′, in accordance with some embodiments. The second gate structure 142b is constructed by the interfacial layer (not shown), the gate dielectric layer 146, and the second gate electrode layer 148b. The material of the second gate electrode layer 148b is different from that of the first gate electrode layer 148a. There is an interface between the first gate electrode layer 148a and the second gate electrode layer 148b. The bottom surface of the first gate structure 162a is higher than the bottom surface of the dielectric wall 124. In addition, the bottom surface of the second gate structure 162b is higher than the bottom surface of the dielectric wall 124.

The second gate structure 162b is wrapped around the nanostructures 108′ of the second stack structure 104b. In some embodiments, the second gate electrode layer 158b is formed on the gate dielectric layer 154. In some embodiments, the second gate electrode layer 158b is made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the second gate electrode layer 158b is formed using chemical vapor deposition (CVD), atomic layer deposition (ALD), electroplating, another applicable method, or a combination thereof.

Next, as shown in FIG. 7F, a cut structure 170 is formed over the dielectric wall 124. The cut structure 170 is in direct contact with the gate dielectric layer 154, the first gate electrode layer 158a and the second gate electrode layer 158b. The cut structure 170 is used to isolate the first gate structure 162a and the second gate structure 162b. The first gate structure 162a is separated from the second gate structure 162b by the cut structure 170.

In some embodiments, the cut structure 170 is made of oxide, such as SiO₂, SiOCN, SiON, or the like. In some embodiments, the cut structure 170 is made of a high k dielectric material, such as HfO₂, ZrO₂, HfAlOₓ, HfSiOₓ, Al₂O₃, or the like. In some embodiments, the cut structure 160 is formed by performing ALD, CVD, PVD, other suitable process, or combinations thereof.

If the dielectric wall 124 is removed by an etching process, the side portion of the dielectric wall 124 may be over-etched and causing the shrinkage of the dielectric wall 124. Furthermore, if the dielectric wall 124 is not formed well, the cut isolation structure cannot be formed well on the dielectric wall 124. By changing the fabrication step of forming the dielectric wall 124, the dielectric wall 124 is formed after the first portion 116a of the isolation structure 116 is formed. In addition, the dielectric wall 124 is removed by CMP process, rather than by the etching process. The risk of over-etching issue of the side of the dielectric wall 124 and the shrinkage issue of the dielectric wall 124 are reduced. In addition, the dielectric wall 124 is isolated from the substrate 102 by the isolation structure 116, and therefore the leakage is reduced. Therefore, the performance of the semiconductor structure is improved.

FIG. 7F′ illustrates a cross-sectional view of the semiconductor structure 100b, in accordance with some embodiments. The semiconductor structure 100b of FIG. 7F′ includes elements that are similar to, or the same as, elements of the semiconductor structure 100a of FIG. 7, the difference between the FIG. 7F′ and FIG. 7 is the liner dielectric layer 122 is formed before the dielectric wall 124 is formed. The dielectric wall 124 is surrounded by the liner dielectric layer 122. The liner dielectric layer 122 is an adhesion layer. The liner dielectric layer 122 is in direct contact with the nanostructure 108′.

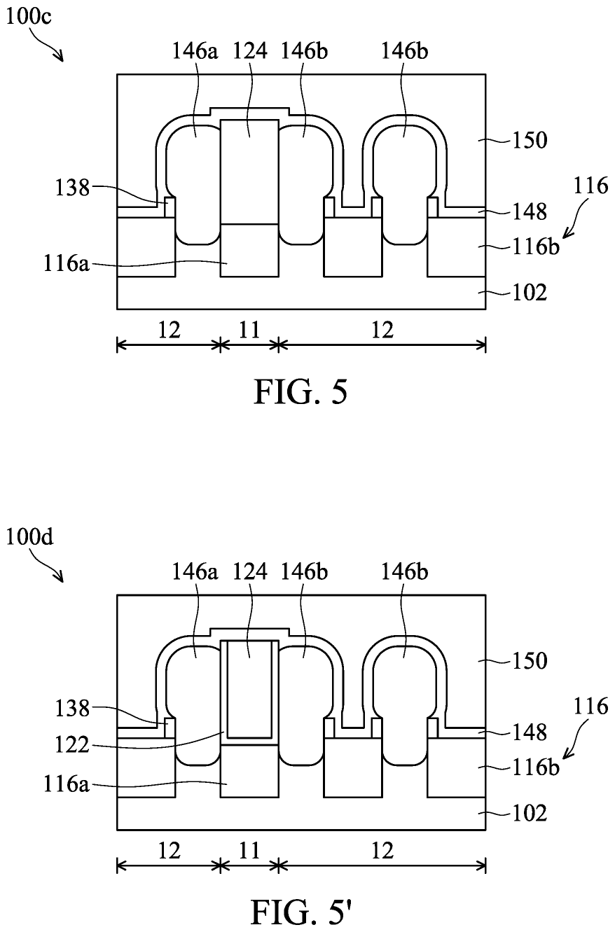

FIG. 8 shows a top view of a semiconductor structure 200a of FIG. 7F, in accordance with some embodiments. FIG. 7F illustrates a cross-sectional representation of the semiconductor structure 100a shown along line C-C′ in FIG. 8, in accordance with some embodiments.

As shown in FIG. 8, the semiconductor structure 200a includes a first device 10 and a second device 20 is arranged next to the first device 10. The first device 10 is a forksheet field-effect transistor device, and the second device 20 is another forksheet field-effect transistor device.

The first device 10 includes the first stack structure 104a and the second stack structure 104b along the first direction (such as X-axis). The second device 20 includes the third stack structure 104c and the fourth stack structure 104d along the first direction (such as X-axis). The first dielectric wall 124a is between the first stack structure 104a and the second stack structure 104b. The second dielectric wall 124b is between the third stack structure 104c and the fourth stack structure 104d. The first gate electrode layer 158a of the first gate structure 162a is formed across the first stack structure 104a, and the second gate electrode layer 158b of the second gate structure 162b is formed across the second stack structure 104b. The cut structure 170 is on and in direct contact with the dielectric wall 124. The first gate structure 162a is separated from the second gate structure 162b by the cut structure 170.

In some embodiments, the dielectric wall 124 has the first width W₁ along the second direction (e.g. the Y-axis). The first width W₁ is the distance between the first stack structure 104a and the second stack structure 104b. In some embodiments, there is the first distance D₁ between the second stack structure 104b and the third stack structure 140c along the second direction (e.g. the Y-axis). In some embodiments, the first width W₁ of the dielectric wall 124 is substantially equal to the first distance D₁.

The first width W₁ of the dielectric wall 124 may be equal to, greater than or smaller than the first distance D₁ according to actual application. Since the dielectric wall 124 is formed after the first portion 116a of the isolation structure 116 is formed, the dielectric wall 124 can be designed according need and is not limited by the dimensions of the first width W₁ and the first distance D₁.

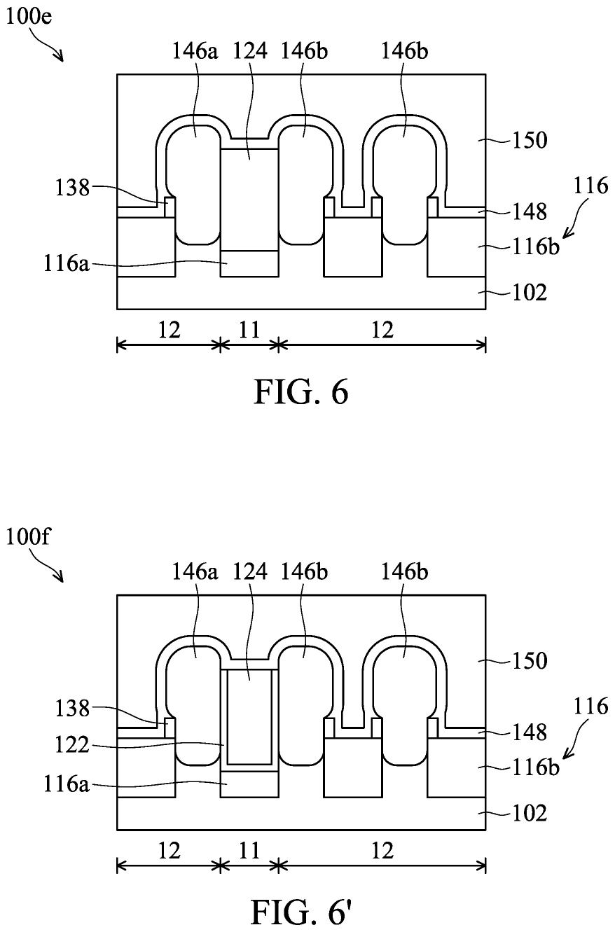

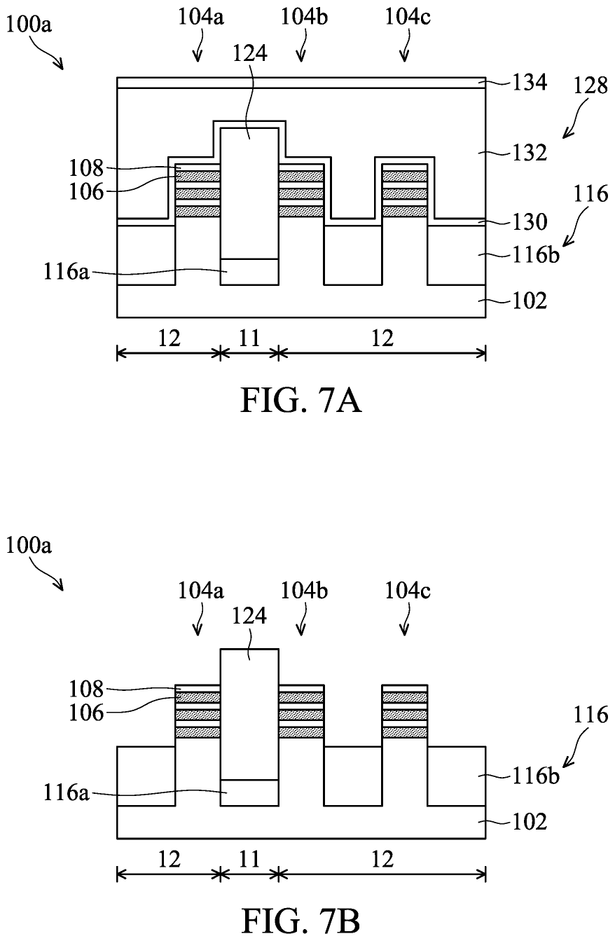

FIG. 9A shows a top view of a semiconductor structure 200b, in accordance with some embodiments. The gate structure is not shown in FIG. 9A to simplify the present disclosure. The semiconductor structure 200b of FIG. 9A includes elements that are similar to, or the same as, elements of the semiconductor structure 200a of FIG. 8, the difference between the FIG. 9A and FIG. 8 is the first width W₁ is greater than the first distance D₁.

FIG. 9B shows a top view of a semiconductor structure 200c, in accordance with some embodiments. The gate structure is not shown in FIG. 9B to simplify the present disclosure. The semiconductor structure 200c of FIG. 9B includes elements that are similar to, or the same as, elements of the semiconductor structure 200b of FIG. 9A, the difference between the FIG. 9B and FIG. 9A is the void 125 is formed in the dielectric wall 124.

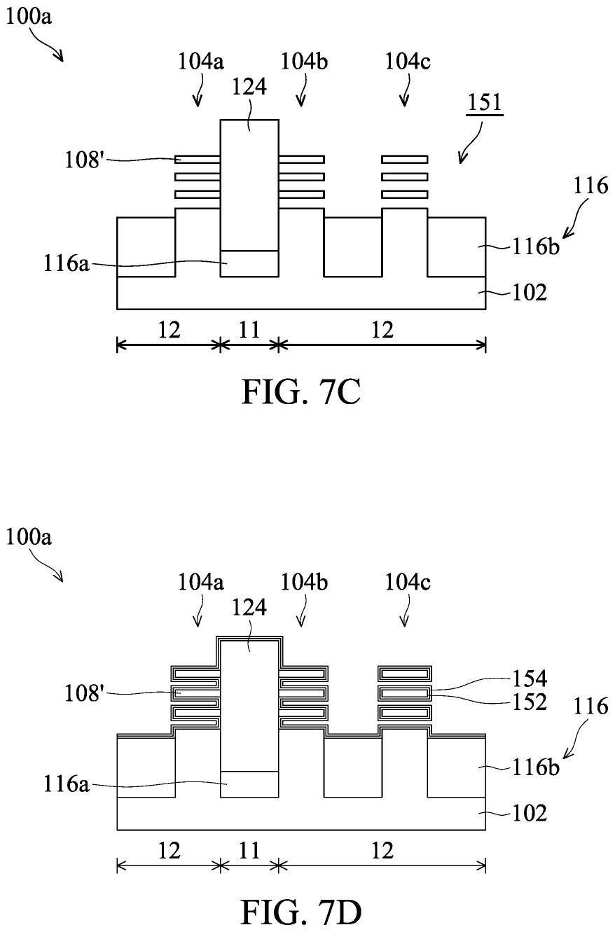

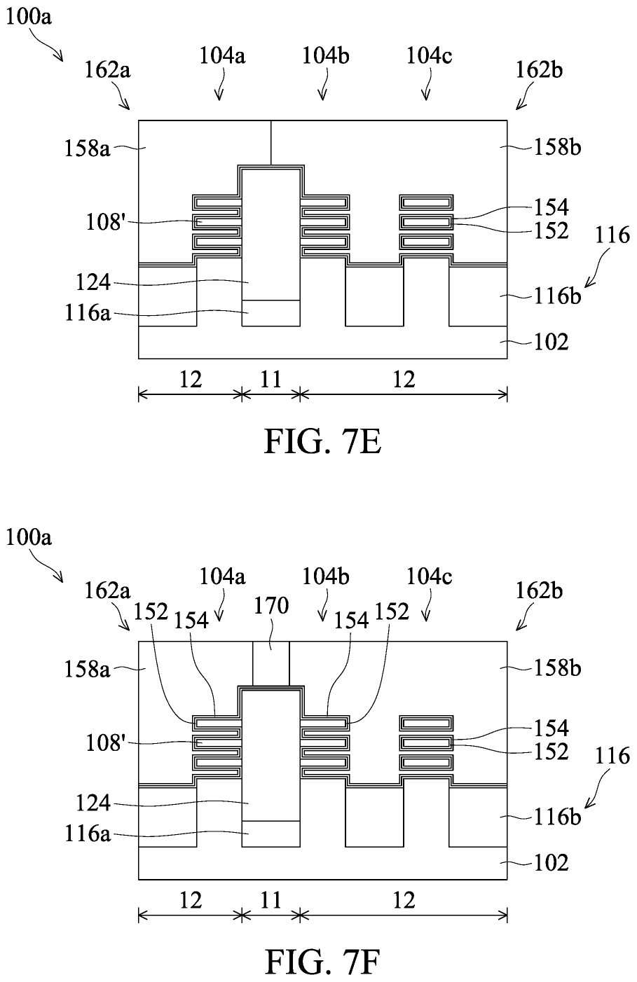

FIG. 10A shows a top view of a semiconductor structure 200d, in accordance with some embodiments. The gate structure is not shown in FIG. 10A to simplify the present disclosure. The semiconductor structure 200d of FIG. 10A includes elements that are similar to, or the same as, elements of the semiconductor structure 200a of FIG. 8, the difference between the FIG. 10A and FIG. 8 is the first width W₁ is smaller than the first distance D₁.

FIG. 10B shows a top view of a semiconductor structure 200e, in accordance with some embodiments. The gate structure is not shown in FIG. 10B to simplify the present disclosure. The semiconductor structure 200e of FIG. 10B includes elements that are similar to, or the same as, elements of the semiconductor structure 200d of FIG. 10A, the difference between the FIG. 10B and FIG. 10A is the void 125 is formed in the dielectric wall 124.

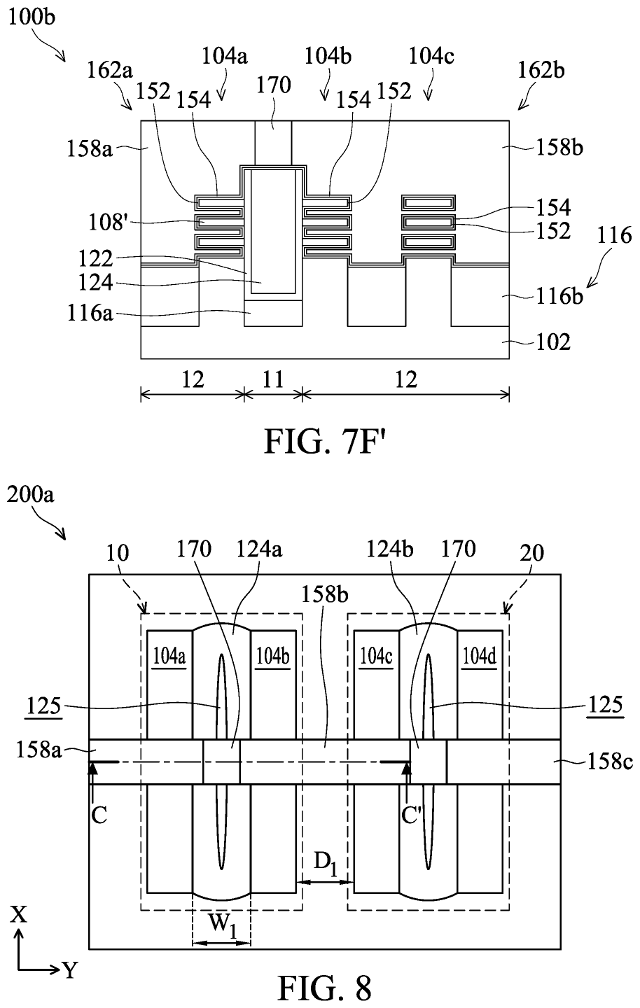

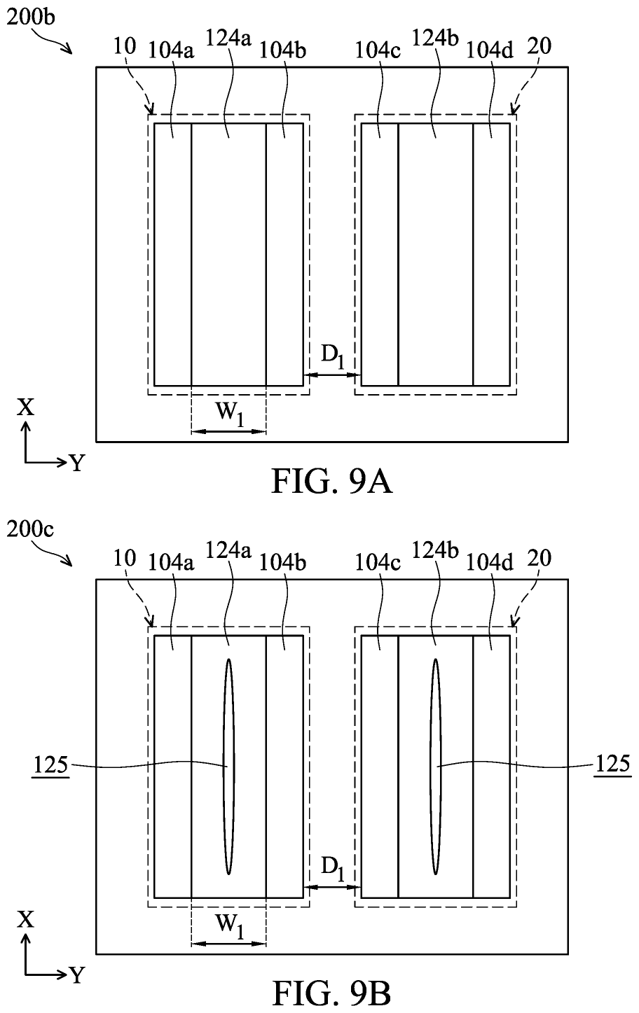

FIG. 11A shows a top view of a semiconductor structure 200f, in accordance with some embodiments. The gate structure is not shown in FIG. 11A to simplify the present disclosure. The semiconductor structure 200f of FIG. 11A includes elements that are similar to, or the same as, elements of the semiconductor structure 200a of FIG. 8. The semiconductor structure 200f includes the first device 10, the second device 20 and a third device 30. The first device 10 is next to the second device 20. The first device 10 is a forksheet field-effect transistor device with the first dielectric wall 124 between the first stack structure 104a and the second stack structure 104b, and the second device 20 is a gate all around (GAA) transistor device free of the dielectric wall. There is no dielectric wall between the first stack structure 104a and the second stack structure 104b in the second device 20. The third device 30 is another forksheet field-effect transistor device with the second dielectric wall 124b between the third stack structure 104c and the fourth stack structure 104d.

The first stack structure 104a extends from the first device 10 to the second device 20, and the second stack structure 104b extends from the first device 10 to the second device 20. In the second device 20, there is a second distance D₂ between the first stack structure 104a and the second stack structure 104b. In some embodiments, the second distance D₂ is substantially equal to the first width W₁.

FIG. 11B shows a top view of a semiconductor structure 200g, in accordance with some embodiments. The gate structure is not shown in FIG. 11B to simplify the present disclosure. The semiconductor structure 200g of FIG. 11B includes elements that are similar to, or the same as, elements of the semiconductor structure 200f of FIG. 11A, the difference between the FIG. 11B and FIG. 11A is the void 125 is formed in the dielectric wall 124.

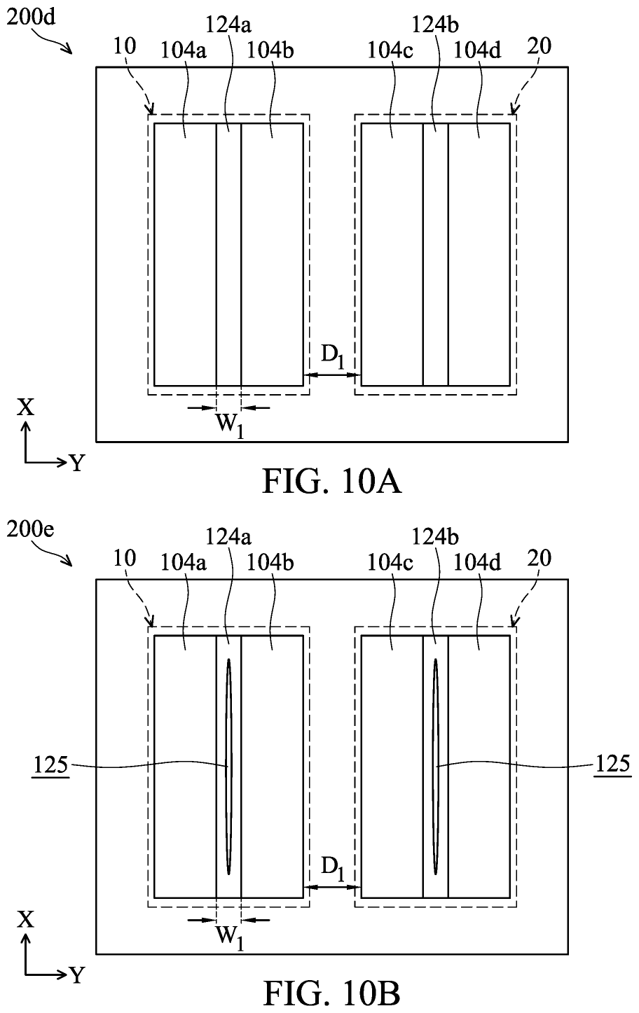

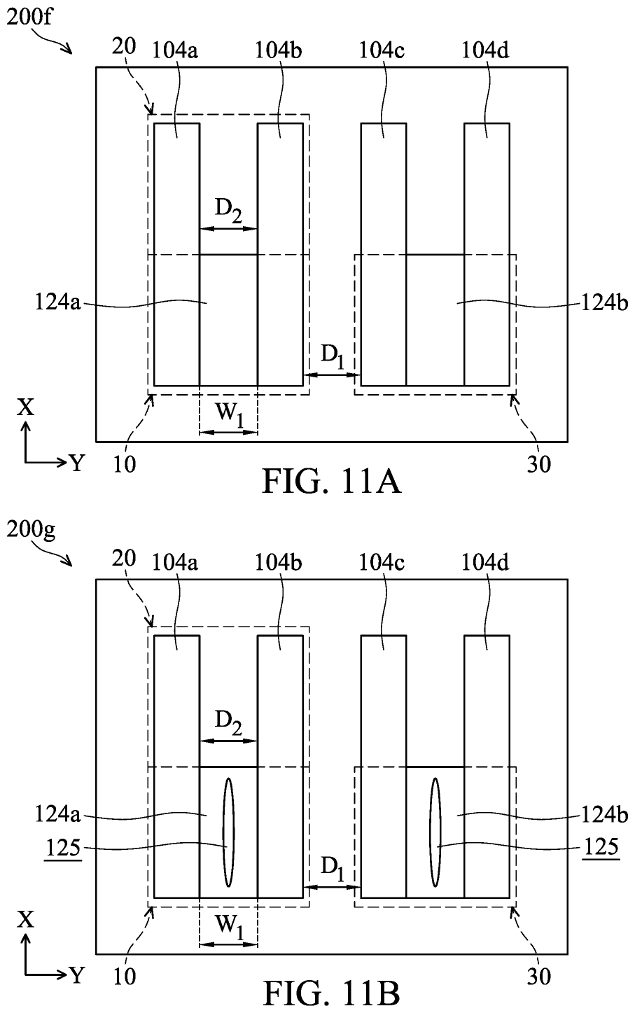

FIG. 12A shows a top view of a semiconductor structure 200h, in accordance with some embodiments. The gate structure is not shown in FIG. 12A to simplify the present disclosure. The semiconductor structure 200h of FIG. 12A includes elements that are similar to, or the same as, elements of the semiconductor structure 200a of FIG. 8.

The semiconductor structure 200h includes the first device 10 and the second device 20. The second device 20 is next to the first device 10 along the first direction (e.g. the X-axis). The first device 10 is a forksheet field-effect transistor device with the dielectric wall 124 between the first stack structure 104a and the second stack structure 104b, and the second device 20 is a gate all around (GAA) transistor device free of the dielectric wall. There is no dielectric wall between the third stack structure 104c and the fourth stack structure 104d in the second device 20.

The dielectric wall 124 has the first width W₁ along the second direction (e.g. the Y-axis). The first stack structure 104a has a width W a along the second direction (e.g. the Y-axis). In some embodiments, the width W a of the first stack structure 104a is in a range from about 5 nm to about 100 nm.

In the second device 20, the third stack structure 104c is arranged in parallel to the fourth stack structure 104d. The first stack structure 104a is in direct contact with the third stack structure 104c, and the second stack structure 104b is direct contact with the fourth stack structure 104d. In some embodiments, the outer sidewall of the first stack structure 104a is aligned with the outer sidewall of the third stack structure 104c. In some embodiments, the outer sidewall of the second stack structure 104b is aligned with the outer sidewall of the fourth stack structure 104d.

The third stack structure 104c has a width Wc along the second direction (e.g. the Y-axis). There is the second distance D₂ between the third stack structure 104c and the fourth stack structure 104d. In some embodiments, the first width W₁ of the dielectric wall 124 is greater than the second distance D₂ between the third stack structure 104c and the fourth stack structure 104d. In some embodiments, the width Wc of the third stack structure 104c is greater than the width Wₐ of the first stack structure 104a. In some embodiments, the difference between the width Wc of the third stack structure 104c and the width Wₐ of the first stack structure 104a is in a range from about 1 nm to about 50 nm.

FIG. 12B shows a top view of a semiconductor structure 200i, in accordance with some embodiments. The gate structure is not shown in FIG. 12B to simplify the present disclosure. The semiconductor structure 200i of FIG. 12B includes elements that are similar to, or the same as, elements of the semiconductor structure 200h of FIG. 12A, the difference between the FIG. 12B and FIG. 12A is the void 125 is formed in the dielectric wall 124.

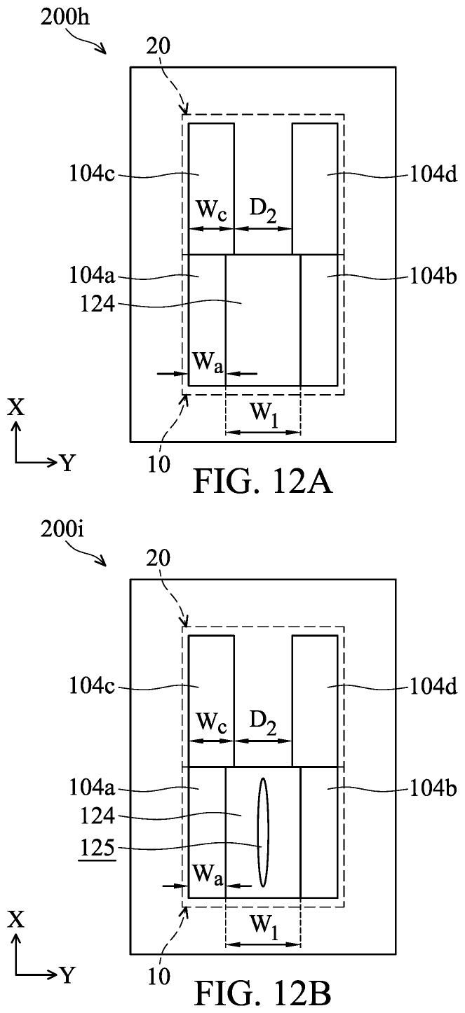

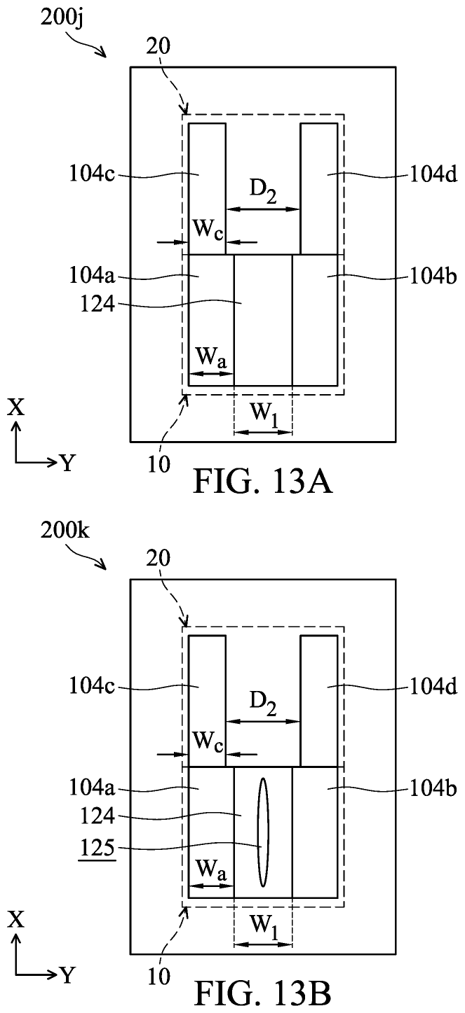

FIG. 13A shows a top view of a semiconductor structure 200j, in accordance with some embodiments. The gate structure is not shown in FIG. 13A to simplify the present disclosure. The semiconductor structure 200j of FIG. 13A includes elements that are similar to, or the same as, elements of the semiconductor structure 200h of FIG. 12A, the difference between the FIG. 13A and FIG. 12A is the first width W₁ of the dielectric wall 124 is smaller than the second distance D₂ between the third stack structure 104c and the fourth stack structure 104d. In addition, the width Wc of the third stack structure 104c is smaller than the width W a of the first stack structure 104a.

FIG. 13B shows a top view of a semiconductor structure 200k, in accordance with some embodiments. The gate structure is not shown in FIG. 13B to simplify the present disclosure. The semiconductor structure 200k of FIG. 13B includes elements that are similar to, or the same as, elements of the semiconductor structure 200j of FIG. 13A, the difference between the FIG. 13B and FIG. 13A is the void 125 is formed in the dielectric wall 124.

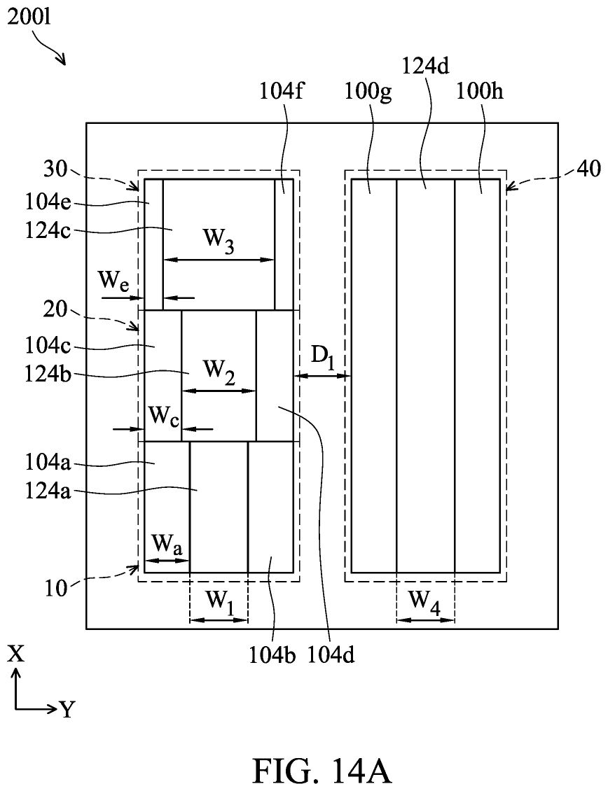

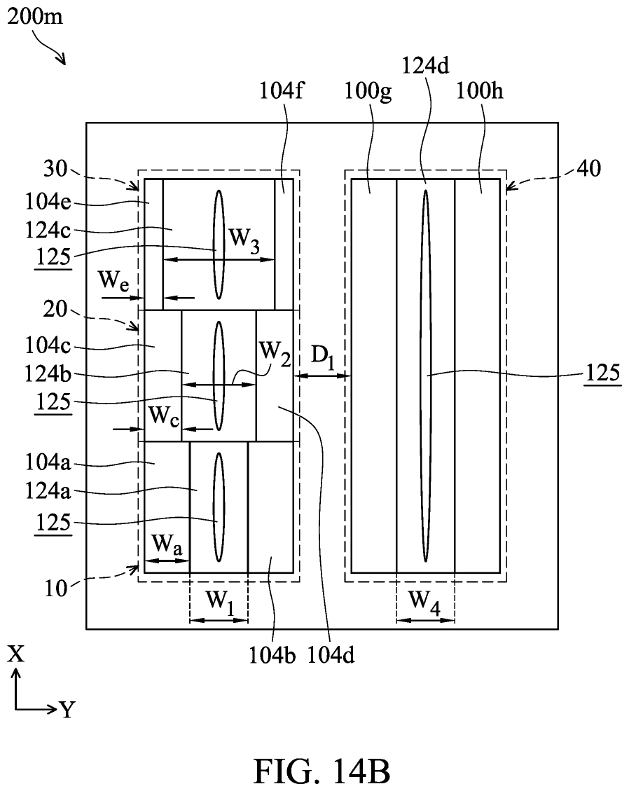

FIG. 14A shows a top view of a semiconductor structure 200l, in accordance with some embodiments. The gate structure is not shown in FIG. 14A to simplify the present disclosure. The semiconductor structure 200l of FIG. 14A includes elements that are similar to, or the same as, elements of the semiconductor structure 200h of FIG. 12A.

As shown in FIG. 14A, the semiconductor structure 200l includes the first device 10, the second device 20, the third device 30 and the fourth device 40. The first device 10 is a forksheet field-effect transistor device with the first dielectric wall 124a having the first width W₁ between the first stack structure 104a and the second stack structure 104b. The second device 20 is a forksheet field-effect transistor device with the second dielectric wall 124b having the second width W₂ between the third stack structure 104c and the fourth stack structure 104d. The third device 30 is a forksheet field-effect transistor device with the third dielectric wall 124c having the third width W₃ between the fifth stack structure 104e and the sixth stack structure 104f. The fourth device 40 is a forksheet field-effect transistor device with the fourth dielectric wall 124d having the fourth width W₄ between the sixth stack structure 104g and the seventh stack structure 104h.

In some embodiments, the third width W₃ is greater than the second width W₂, and the second width W₂ is greater than the first width W₁. In some embodiments, the first width W₁ is substantially equal to the fourth width W₄. In some embodiments, there is a ratio (W₁/W₂) between the first width W₁ and the second width W₂ is in a range from about 1.1 to about 3.

The first stack structure 104a has a width Wₐ along the second direction (e.g. the Y-axis). The third stack structure 104c has a width W_{c} along the second direction. The fifth stack structure 104e has a width Wₑ along the second direction (e.g. the Y-axis). In some embodiments, the width Wₐ of the first stack structure 104a is greater than the width W_{c} of the third stack structure 104c, and the width W_{c} of the third stack structure 104c is greater than the width Wₑ of the fifth stack structure 104e.

FIG. 14B shows a top view of a semiconductor structure 200m, in accordance with some embodiments. The gate structure is not shown in FIG. 14B to simplify the present disclosure. The semiconductor structure 200m of FIG. 14B includes elements that are similar to, or the same as, elements of the semiconductor structure 200l of FIG. 14A, the difference between the FIG. 14B and FIG. 14A is the void 125 is formed in the dielectric wall 124.

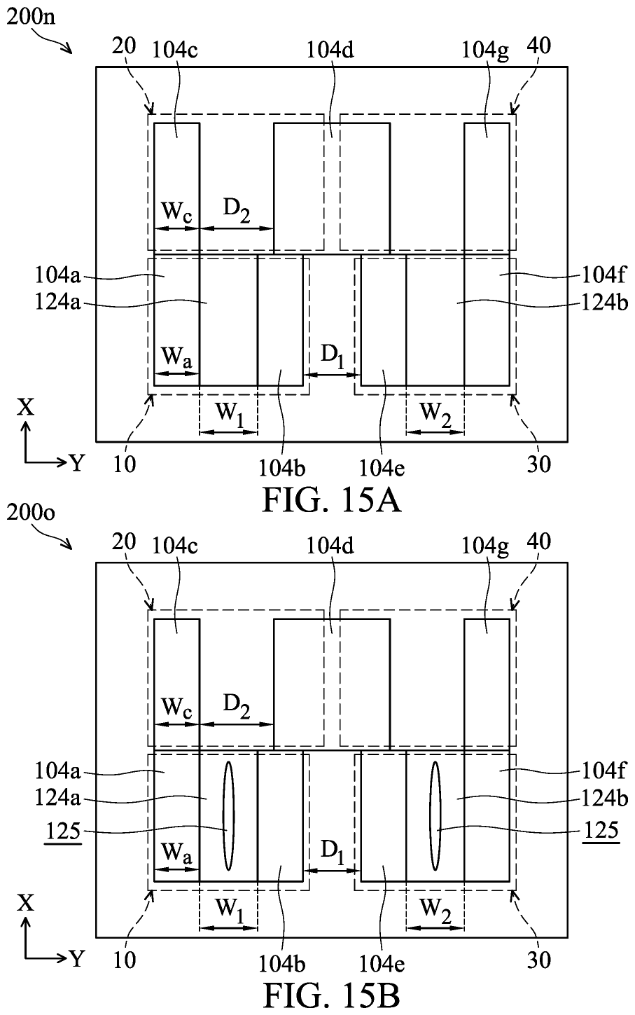

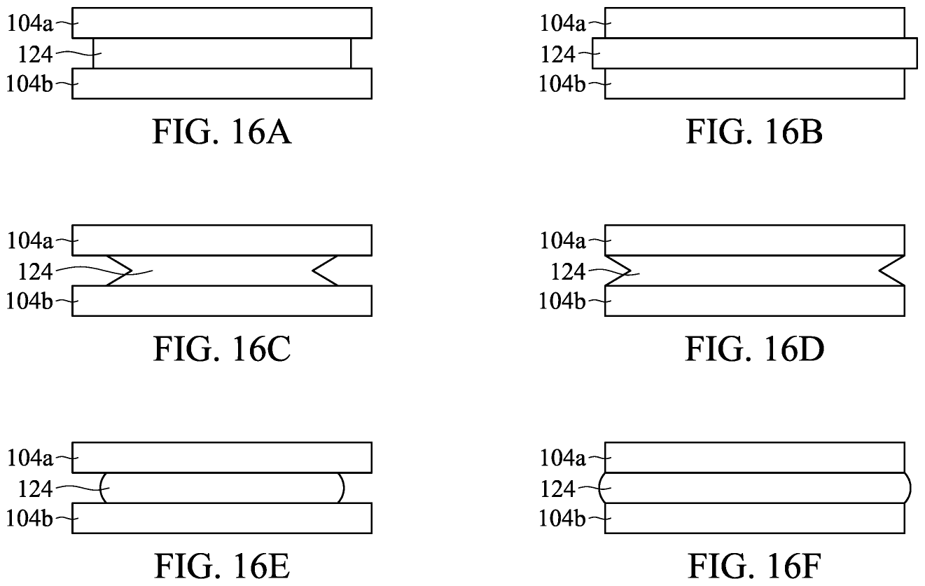

FIG. 15A shows a top view of a semiconductor structure 200n, in accordance with some embodiments. The gate structure is not shown in FIG. 15A to simplify the present disclosure. The semiconductor structure 200n of FIG. 15A includes elements that are similar to, or the same as, elements of the semiconductor structure 200h of FIG. 12A.

The semiconductor structure 200n includes the first device 10, the second device 20, the third device 30 and the fourth device 40. The first device 10 is a forksheet field-effect transistor device with the first dielectric wall 124a having the first width W between the first stack structure 104a and the second stack structure 104b. The third device 30 is another forksheet field-effect transistor device with the second dielectric wall 124b having the second width W₂ between the fifth stack structure 104e and the sixth stack structure 104f. In some embodiments, the first width W₁ of the first stack wall 124a is substantially equal to the second width W₂ of the second dielectric wall 124b.

The second device 20 is a gate all around (GAA) transistor device free of the dielectric wall. The fourth device 40 is another gate all around (GAA) transistor device free of the dielectric wall. The second device 20 includes the third stack structure 104c and the fourth stack structure 104d, and the fourth device 40 includes the fourth stack structure 104d and the seventh stack structure 104g. The fourth stack structure 104d is between the third stack structure 104c and the seventh stack structure 104g. There is a first distance D₁ between the second stack structure 104b and the fifth stack structure 104e. There is a second distance D₂ between the third stack structure 104c and the fourth stack structure 104d. In some embodiments, the second distance D₂ is greater than the first distance D₁.

FIG. 15B shows a top view of a semiconductor structure 200o, in accordance with some embodiments. The gate structure is not shown in FIG. 15B to simplify the present disclosure. The semiconductor structure 200o of FIG. 15B includes elements that are similar to, or the same as, elements of the semiconductor structure 200l of FIG. 15A, the difference between the FIG. 15B and FIG. 15A is the void 125 is formed in the dielectric wall 124.

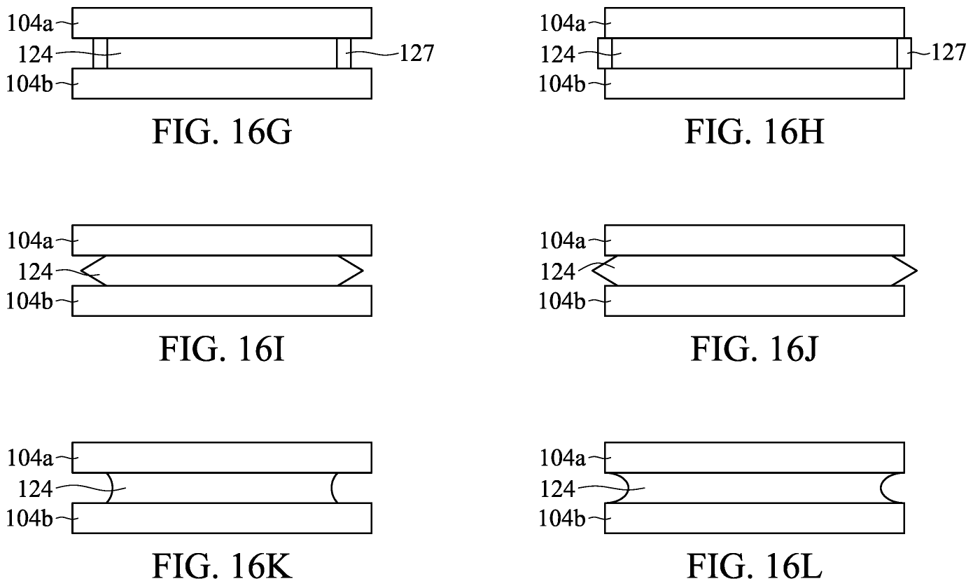

FIGS. 16A to 16L illustrate top views of the semiconductor structure 100a-100f, in accordance with some embodiments.

In FIGS. 16A to 16L, the end of the dielectric wall 124 has a square shape (FIGS. 16A and 16B), a V shape (FIGS. 16C and 16D), a C shape (FIGS. 16E and 16F), an inverted V shape (FIGS. 16I and 16J), or an inverted C shape (FIGS. 16K and 16L) when seen from the top view. In some embodiments, the end of the dielectric wall 124 has multiple layers including an additional layer 127 (FIGS. 16G and 16H). In some embodiments, the dielectric wall 124 124 extends beyond the sidewall of the first stack structure 104a when seen from the top view.

It should be appreciated that the semiconductor structures 100a to 100f having the dielectric wall 124 is formed over the first portion 116a of the isolation structure 116 described above may also be applied to FinFET structures, although not shown in the figures.

It should be noted that same elements in FIGS. 1A to 16L may be designated by the same numerals and may include similar or the same materials and may be formed by similar or the same processes; therefore such redundant details are omitted in the interest of brevity. In addition, although FIGS. 1A to 16L are described in relation to the method, it will be appreciated that the structures disclosed in FIGS. 1A to 16L are not limited to the method but may stand alone as structures independent of the method. Similarly, although the methods shown in FIGS. 1A to 16L are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes forming a first stack structure and a second stack structure formed over a substrate. The first portion of the isolation structure is formed over the substrate. The dielectric wall is formed over the first portion of the isolation structure and between the first stack structure and the second stack structure. The gate structure is formed over the dielectric wall, the first stack structure and the second stack structure. The dielectric wall is formed after the first portion of the isolation structure 116 is formed. In addition, the dielectric wall is removed by CMP process, rather than by the etching process. The risk of over-etching issue of the side of the dielectric wall and the shrinkage issue of the dielectric wall are reduced. In addition, the dielectric wall is isolated from the substrate by the isolation structure, and therefore the leakage is reduced. Therefore, the performance of the semiconductor structure is improved.

In some embodiments, a semiconductor structure is provided. The semiconductor structure includes an isolation structure formed over a substrate, and a first stack structure extended above the isolation structure. The first stack structure comprises a plurality of first nanostructures along a first direction. The semiconductor structure also includes a second stack structure formed adjacent to the first stack structure, and the second stack structure includes a plurality of second nanostructures along the first direction. The semiconductor structure includes a first gate structure formed over the first stack structure. The first gate structure extends along a second direction. The semiconductor structure includes a first dielectric wall between the first stack structure and the second stack structure. The first dielectric wall is directly over a first portion of the isolation structure and surrounded by a second portion of the isolation structure. The top surface of the first portion of the isolation structure is lower than the top surface of the second portion of the isolation structure.

In some embodiments, a semiconductor structure is provided. The semiconductor structure includes a first device and a second device. The first device includes a first stack structure extended above an isolation structure along a first direction, a second stack structure formed adjacent to the first stack structure, and a first dielectric wall between the first stack structure and the second stack structure, wherein the first dielectric wall has a first width along a second direction. The second device includes a third stack structure extends along the first direction, and the third stack structure is in direct contact with the first stack structure; a fourth stack structure extends along the first direction, and the fourth stack structure is in direct contact with the second stack structure, and a second dielectric wall between the third stack structure and the fourth stack structure, and the second dielectric wall has a second width along a second direction, and the second width is greater than the first width.

In some embodiments, a method for forming a semiconductor structure is provided. The method includes forming a first stack structure and a second stack structure over a substrate, and forming an isolation material over the first stack structure and the second stack structure. The method includes removing a first portion of the isolation material in a first region to form a recess, and forming a dielectric wall in the recess. The dielectric wall is between the first stack structure and the second stack structure. The top surface of the dielectric wall is higher than the top surface of the first stack structure. The method includes removing a second portion of the isolation material in a second region to form an isolation structure and to expose the dielectric wall. The isolation structure has a first portion in the first region and a second portion in the second region, and the top surface of the first portion of the isolation structure is lower than the top surface of the second portion of the isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
an isolation structure formed over a substrate;
a first stack structure extended above the isolation structure, wherein the first stack structure comprises a plurality of first nanostructures along a first direction;
a second stack structure formed adjacent to the first stack structure, wherein the second stack structure comprises a plurality of second nanostructures along the first direction;
a first gate structure formed over the first stack structure, wherein the first gate structure extends along a second direction; and
a first dielectric wall between the first stack structure and the second stack structure, wherein the first dielectric wall is directly over a first portion of the isolation structure and surrounded by a second portion of the isolation structure, and a top surface of the first portion of the isolation structure is lower than a top surface of the second portion of the isolation structure.

2. The semiconductor structure as claimed in claim 1, wherein a bottom surface of the first portion of the isolation structure is substantially level with a bottom surface of the second portion of the isolation structure.

3. The semiconductor structure as claimed in claim 1, further comprising:
an S/D structure formed adjacent to the gate structure, wherein the top surface of the first portion of the isolation structure is lower than a bottom surface of the S/D structure.

4. The semiconductor structure as claimed in claim 1, further comprising:
a third stack structure formed adjacent to the second stack structure, wherein the third stack structure comprises a plurality of third nanostructures along the first direction, wherein the first dielectric wall has a first width along the second direction, and there is a distance between the second stack structure and the third stack structure along the second direction, and the first width is larger than or smaller than the distance.

5. The semiconductor structure as claimed in claim 1, further comprising:
a third stack structure formed adjacent to the first stack structure;
a fourth stack structure formed adjacent to the second stack structure; and
a second dielectric wall between the third stack structure and the fourth stack structure, wherein the first dielectric wall has a first width along the second direction, the second dielectric wall has a second width along the second direction, and the second width is greater than the first width.

6. The semiconductor structure as claimed in claim 1, further comprising:
a third stack structure formed adjacent to the first stack structure; and
a fourth stack structure formed adjacent to the second stack structure, wherein there is no dielectric wall between the third stack structure and the fourth stack structure along the second direction, and the first dielectric wall has a first width along the second direction, and the first width is larger than or smaller than the distance.

7. The semiconductor structure as claimed in claim 1, wherein the first dielectric wall extends beyond a sidewall of the first stack structure when seen from a top view.

8. The semiconductor structure as claimed in claim 1, wherein there is a void in the first dielectric wall when seen from a top view.

9. The semiconductor structure as claimed in claim 1, wherein the first dielectric wall and the isolation structure are made of different materials.

10. The semiconductor structure as claimed in claim 1, wherein an end of the first dielectric wall has a V shape, a C shape, a rectangular shape, an inverted V shape, or an inverted C shape when seen from a top view.

11. A semiconductor structure, comprising:
a first device, comprising:
a first stack structure extended above an isolation structure along a first direction;
a second stack structure formed adjacent to the first stack structure; and
a first dielectric wall between the first stack structure and the second stack structure, wherein the first dielectric wall has a first width along a second direction; and
a second device, comprising:
a third stack structure extended along the first direction, wherein the third stack structure is in direct contact with the first stack structure;
a fourth stack structure extended along the first direction, wherein the fourth stack structure is in direct contact with the second stack structure; and
a second dielectric wall between the third stack structure and the fourth stack structure, wherein the second dielectric wall has a second width along a second direction, and the second width is greater than the first width.

12. The semiconductor structure as claimed in claim 11, further comprising:
a third device comprising:
a fifth stack structure extended along the first direction, wherein the fifth stack structure is in direct contact with the third stack structure;
a sixth stack structure extended along the first direction, wherein the sixth stack structure is in direct contact with the fourth stack structure; and
a third dielectric wall between the fifth stack structure and the sixth stack structure, wherein the third dielectric wall has a third width along the second direction, and the third width is greater than the second width.

13. The semiconductor structure as claimed in claim 11, wherein the isolation structure comprises a first portion and a second portion, the first portion is directly below the first dielectric wall, the second portion is surrounded by the dielectric wall, and a top surface of the first portion of the isolation structure is lower than a top surface of the second portion of the isolation structure.

14. The semiconductor structure as claimed in claim 11, wherein the first stack structure has a first width along the second direction, and the third stack structure has a second width along the second direction, and the first width is greater than the second width.

15. The semiconductor structure as claimed in claim 11, wherein there is a void in the first dielectric wall when seen from a top view.

16. A method for forming a semiconductor structure, comprising:
forming a first stack structure and a second stack structure over a substrate;
forming an isolation material over the first stack structure and the second stack structure;
removing a first portion of the isolation material in a first region to form a recess;
forming a dielectric wall in the recess, wherein the dielectric wall is between the first stack structure and the second stack structure, and a top surface of the dielectric wall is higher than a top surface of the first stack structure;
removing a second portion of the isolation material in a second region to form an isolation structure and to expose the dielectric wall, wherein the isolation structure has a first portion in the first region and a second portion in the second region, a top surface of the first portion of the isolation structure is lower than a top surface of the second portion of the isolation structure.

17. The method for forming the semiconductor structure as claimed in claim 16, further comprising:
forming a mask structure over the first stack structure; and
removing the mask structure before removing the second portion of the isolation material in the second region.

18. The method for forming the semiconductor structure as claimed in claim 16, further comprising:
forming an S/D structure adjacent to the dielectric wall, wherein the top surface of the first portion of the isolation structure is lower than a bottom surface of the S/D structure.

19. The method for forming the semiconductor structure as claimed in claim 16, wherein the first stack structure comprises a plurality of first semiconductor layers and a plurality of second semiconductor layers, and the method further comprises removing the first semiconductor layers to form a trench, and forming a gate structure in the trench.

20. The method for forming the semiconductor structure as claimed in claim 19, wherein a bottom surface of the gate structure is higher than a bottom surface of the dielectric wall.
